(19) United States
(12) Patent Application Publication
(10) Pub. No.: US 2024/0247093 A1
(43) Pub. Date: Jul. 25, 2024

(54) MULTI-PITCH TOLERABLE BLOCK COPOLYMERS WITH ENHANCED KINETICS FOR DIRECTED SELF-ASSEMBLY APPLICATIONS

(71) Applicant: Merck Patent GmbH, Darmstadt (DE)

(72) Inventors: Md S. RAHMAN, Flemington, NJ (US); Durairaj BASKARAN, Bridgewater, NJ (US); Jin LI, Guangdong (CN); Sachin BOBADE, Somerville, NJ (US); EunJeong JEONG, Gyeonggi-do (KR); Zhong LI, Bridgewater, NJ (US)

(21) Appl. No.: 18/550,587

(22) PCT Filed: Apr. 21, 2022
(86) PCT No.: PCT/EP2022/060506

§ 371 Date: Sep. 14, 2023

Related U.S. Application Data
(60) Provisional application No. 63/178,612, filed on Apr. 23, 2021.

(51) Int. Cl. C08F 297/02; B82Y 40/00; C08F 212/08; C08F 212/32; C09D 153/00; G03F 7/00; G03F 7/004

(52) U.S. Cl. CPC C08F 297/026; C08F 212/08; C08F 212/32; C09D 153/00; G03F 7/0002; G03F 7/004; B82Y 40/00

(57) ABSTRACT

The present invention relates to two different block copolymer families having structures (1) or (6) which both have a polydispersity ranging from 1 to about 1.09. In structure (1), A is a polar block copolymer segment comprised of either alkyl 2-methylenealkanoate derived repeating units, lactone derived repeat units, oxirane derived repeat units, oxetane or cyclic carbonate derived repeat units; L is either a direct valence bond or a linking moiety derived from a 1, 1-diarylethene; B segment is a non-polarblock copolymer segment comprised of styrenic repeat unit, E are end groups selected; and wherein said block copolymer is multi-tethered with oligo flexible tethered groups at various positions as outlined. In structure (6), Aᵢ is a polar block copolymer segment which has T_{g} of about 50° C. and to about 100° C.; comprised of alkyl 2-methylenealkanoate derived repeating units, lactone derived repeat units, oxirane derived repeat units, oxetane or cyclic carbonate derived repeat units; Bᵢ is a styrenic block copolymer segment, which has a T_{g} from about 50° C. and to about 100° C., B2 is a block copolymer segment with a T_{g} ranging from about −5° C. to about −50° C., The present invention also pertains to compositions comprising either the block copolymer having structures (1) or the block copolymer having structure (6) and to methods of using these compositions. E-A-L-B-L-A-E (1) E₁-A₁-L₁-B₂-B₁—B₂-L₁-A1-E₁(6)

### FIELD OF THE INVENTION

The invention relates to two different block copolymer families having respectively general structures (1) and (6), and two compositions comprising block copolymers from one of these two families and to novel methods for using the block copolymer compositions for aligning microdomains of self-assembling block copolymers (BCP) to form self-assembled geometries which are useful for forming arrays of contact holes or lines and spaces. These compositions and processes are useful for fabrication of electronic devices.

### BACKGROUND

Self-assembly of block copolymers is a method useful for generating smaller and smaller patterned features for the manufacture of microelectronic devices in which the critical dimensions (CD) of features on the order of nanoscale can be achieved. Self-assembly methods are desirable for extending the resolution capabilities of microlithographic technology for repeating features such as an array of contact holes or posts. In a conventional lithography approach, ultraviolet (UV) radiation may be used to expose through a mask onto a photoresist layer coated on a substrate or layered substrate. Positive or negative photoresists are useful, and these can also contain a refractory element such as silicon to enable dry development with conventional integrated circuit (IC) plasma processing. In a positive photoresist, UV radiation transmitted through a mask causes a photochemical reaction in the photoresist such that the exposed regions are removed with a developer solution or by conventional IC plasma processing. Conversely, in negative photoresists, UV radiation transmitted through a mask causes the regions exposed to radiation to become less removable with a developer solution or by conventional IC plasma processing. An integrated circuit feature, such as a gate, via or interconnect, is then etched into the substrate or layered substrate, and the remaining photoresist is removed. When using conventional lithographic exposure processes, the dimensions of features of the integrated circuit feature are limited. Further reduction in pattern dimensions are difficult to achieve with radiation exposure due to limitations related to aberrations, focus, proximity effects, minimum achievable exposure wavelengths and maximum achievable numerical apertures. The need for large-scale integration has led to a continued shrinking of the circuit dimensions and features in the devices. In the past, the final resolution of the features has been dependent upon the wavelength of light used to expose the photoresist, which has its own limitations. Directed (a.k.a. guided) self-assembly techniques, such as graphoepitaxy and chemoepitaxy using block copolymer imaging, which employ a patterned area on a substrate, are highly desirable techniques used to enhance resolution while reducing CD variation. These techniques can be employed to either enhance conventional UV lithographic techniques or to enable even higher resolution and CD control in approaches employing EUV, e-beam, deep UV or immersion lithography. The directed self-assembly block copolymer comprises a block of etch resistant copolymeric unit and a block of highly etchable copolymeric unit, which when coated, aligned and etched on a substrate give regions of very high-density patterns.

For directed (guided), or unguided self-assembly, of a block copolymer film, respectively, on a patterned or non-patterned substrate area, typically the self-assembly process of this block polymer layer occurs during annealing of this film overlying a neutral layer. This neutral layer over a semiconductor substrate may be an unpatterned neutral layer, or in chemoepitaxy or graphoepitaxy, this neutral layer may contain, respectively, graphoepitaxy or chemoepitaxy guiding features (formed through the above described UV lithographic technique). During annealing of the block copolymer film, the underlying, neutral layer, directs the nano-phase separation of the block copolymer domains. One example is the formation phase separated domains which are lamellas or cylinders perpendicular to the underlying neutral layer surface. These nano-phase separated block copolymer domains, form a pre-pattern (e.g., line and space L/S) which may be transferred into the substrate through an etching process (e.g., plasma etching). In graphoepitaxy, or in chemoepitaxy, these guiding features may dictate both pattern rectification and pattern multiplication. In the case of an unpatterned neutral layer this produces a repeating array of for instance L/S or CH. For example, in a conventional block copolymer such as poly(styrene-b-methyl methacrylate (P(S-b-MMA)), in which both blocks have similar surface energies at the BCP-air interface, this can be achieved by coating and thermally annealing the block copolymer on a layer of non-preferential or neutral material that is grafted or cross-linked at the polymer-substrate interface.

In the graphoepitaxy directed self-assembly method, the block copolymers self organizes around a substrate that is pre-patterned with conventional lithography (Ultraviolet, Deep UV, e-beam, Extreme UV (EUV) exposure source) to form repeating topographical features such as a line/space (L/S) or contact hole (CH) pattern. In an example of a L/S directed self-assembly array, the block copolymer can form self-aligned lamellar regions which can form parallel line-space patterns of different pitches in the trenches between pre-patterned lines, thus enhancing pattern resolution by subdividing the space in the trench between the topographical lines into finer patterns. For example, a diblock copolymer or a triblock copolymer which is capable of microphase separation and comprises a block rich in carbon (such as styrene or containing some other element like Si, Ge, Ti) which is resistant to plasma etch, and a block which is highly plasma etchable or removable, can provide a high-resolution pattern definition. Examples of highly etchable blocks can comprise monomers which are rich in oxygen, and which do not contain refractory elements and are capable of forming blocks which are highly etchable, such as methyl methacrylate. The plasma etching gases used in the etching process of defining the self-assembly pattern typically are those used in processes employed to make integrated circuits (IC). In this manner, very fine patterns can be created in typical IC substrates than were definable by conventional lithographic techniques, thus achieving pattern multiplication. Similarly, features such as contact holes can be made denser by using graphoepitaxy in which a suitable block copolymer arranges itself by directed self-assembly around an array of contact holes or posts defined by conventional lithography, thus forming a denser array of regions of etchable and etch resistant domains which when etched give rise to a denser array of contact holes. Consequently, graphoepitaxy has the potential to offer both pattern rectification and pattern multiplication.

In chemical epitaxy, or pinning chemical epitaxy, the self-assembly of the block copolymer is formed on a surface whose guiding features are regions of differing chemical affinity, having no, or insignificant topography (a.k.a. non-guiding topography) which predicates the directed self-assembly process. For example, the surface of a substrate could be patterned with conventional lithography (UV, Deep UV, e-beam EUV) to create surfaces of different chemical affinity in a line and space (L/S) pattern in which exposed areas whose surface chemistry had been modified by irradiation alternate with areas which are unexposed and show no chemical change. These areas present no topographical difference but do present a surface chemical difference or pinning to direct self-assembly of block copolymer segments. Specifically, the directed self-assembly of a block copolymer whose block segments contain etch resistant (such as styrene repeat unit) and rapidly etching repeat units (such as methyl methacrylate repeat units) would allow precise placement of etch resistant block segments and highly etchable block segments over the pattern. This technique allows for the precise placement of these block copolymers and the subsequent pattern transfer of the pattern into a substrate after plasma or wet etch processing. Chemical epitaxy has the advantage that it can be fine-tuned by changes in the chemical differences to help improve line-edge roughness and CD control, thus allowing for pattern rectification. Other types of patterns such as repeating contact holes (CH) arrays could also be pattern rectified using chemoepitaxy.

These neutral layers are layers on a substrate or the surface of a treated substrate which have no affinity for either of the block segment of a block copolymer employed in directed self-assembly. In the graphoepitaxy method of directed self-assembly of block copolymer, neutral layers are useful as they allow the proper placement or orientation of block polymer segments for directed self-assembly which leads to proper placement of etch resistant block polymer segments and highly etchable block polymer segments relative to the substrate. For instance, in surfaces containing line and space features which have been defined by conventional radiation lithography, a neutral layer allows block segments to be oriented so that the block segments are oriented perpendicular to the surface of the substrates, an orientation which is ideal for both pattern rectification and pattern multiplication depending on the length of the block segments in the block copolymer as related to the length between the lines defined by conventional lithography. If a substrate interacts too strongly with one of the block segments it would cause it to lie flat on that surface to maximize the surface of contact between the segment and the substrate; such a surface would perturb the desirable perpendicular alignment which can be used to either achieve pattern rectification or pattern multiplication based on features created through conventional lithography. Modification of selected small areas or pinning of substrate to make them strongly interactive with one block of the block copolymer and leaving the remainder of the surface coated with the neutral layer can be useful for forcing the alignment of the domains of the block copolymer in a desired direction, and this is the basis for the pinned chemoepitaxy or graphoepitaxy employed for pattern multiplication.

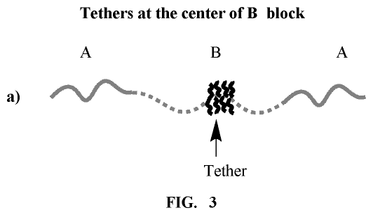

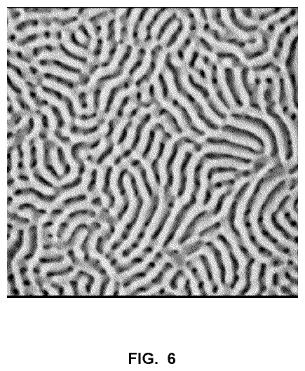

Although self-assembly using polystyrene-b-polymethylmethacrylate (PS-b-PMMA) is widely used as next generation patterning material in lithography, with the nano-phase separation assembly process generating well aligned arrays of domains, this occurs with the formation of considerable amounts of defects, if the film thickness exceeds beyond 50 nm. These defects are significant in contact hole and line/space multiplication processes and need to be reduced significantly to improve device yield in any commercially viable IC-manufacturing employing directed self-assembly. One problem to be solved is that standard di-block copolymers cannot be used in directed self-assembly to affect either pattern multiplication of multipitch pattern. Another problem to be solved is that defect free assembly process of block copolymers requires high thermal energy and much longer annealing times. This difficulty limits application of directed self-assembly of block copolymer with large domain spacing and limits the use of standard AB diblock copolymer and standard triblock copolymers. For standard triblock copolymer which typically have double the molecular weight of standard diblock copolymers, and can undergo multipitch directed self-assembly, this ability in manufacturing worthy multi-pitch applications DSA is hindered by the long annealing times required to affect defect free multipitch directed self-assembly. For example Triblock copolymers of PMMA-b-PS-b-PMMA (ABA) with L₀ 50 nm have been shown to produce multi pitch DSA from 50 nm to 80 nm which is very important for IC industries for design flexibility (FIG. 3 on page 5543 of Ji et al ACS NANO, Ji et al, VOL. 6, NO. 6, pp 5440-5448). This type of ABA Triblock copolymers can produce defect free DSA at bend angle 45, 90 and 135 deg (FIG. 6 on page 5445 of Ji et al ACS NANO, Ji et al, VOL. 6, NO. 6, pp 5440-5448). However, a problem to be solved is that the assembly kinetics This type of ABA Triblock copolymers is 3 times slower than AB type diblock copolymers due to the higher M_{w} as well as changes in the fractions of loop and bridge formation of the middle PS block. It requires about 36 hours of annealing to get defect free DSA on multi pitch, which is not viable for industrial manufacturing. Hence, the development of novel triblock copolymers that can provide a faster kinetics and can orient in conventional underlayers for DSA is very important.

### DETAILED DESCRIPTION OF DRAWINGS

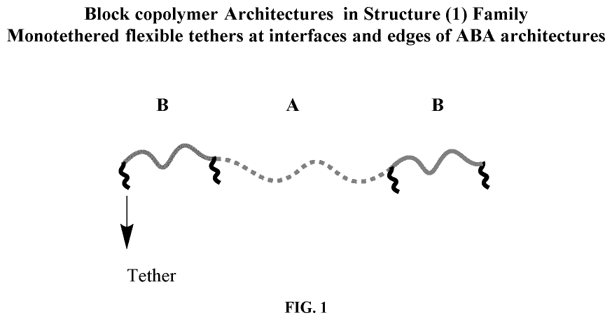

FIG. 1: Block copolymer ABA Architectures in Structure (1) Family Monotethered oligo flexible tethers at interfaces and edges of ABA architectures.

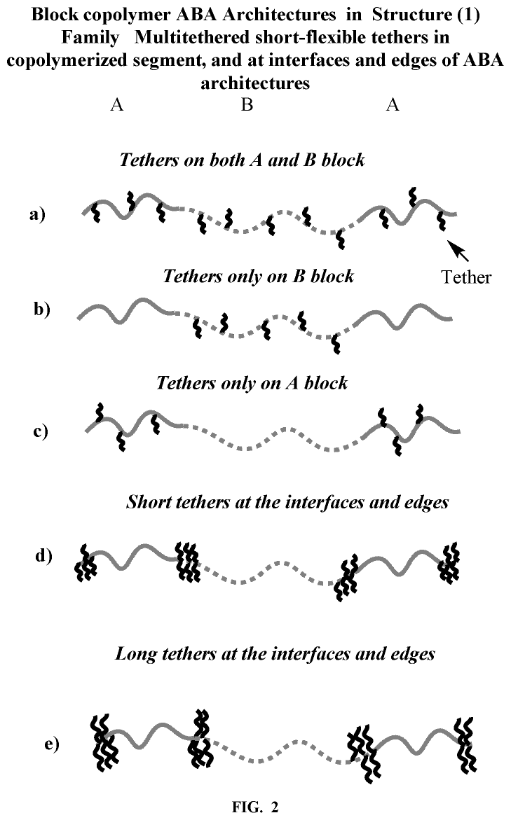

FIG. 2: Block copolymer ABA Architectures in Structure (1) Family Multitethered oligo flexible tethers copolymerized segment, and at interfaces and edges of ABA architectures a) Tethers on both A and B block, b) Tethers only on B block, c) Tethers only on A block, d) short tethers at the interfaces and edges, e) long tethers at the interfaces and edges.

FIG. 3: Block copolymer ABA Architectures in Structure (1) Family Multitethered oligo flexible tethers copolymerized at the center of the middle block of ABA architectures.

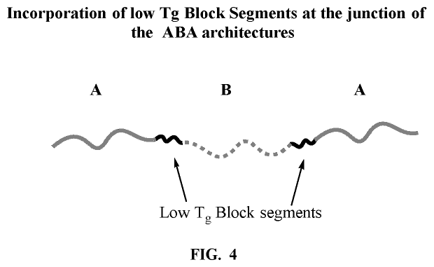

FIG. 4: Block copolymer ABA Architectures in Structure (6) Incorporation of low T_{g} Block Segments at the junctions of the ABA architectures.

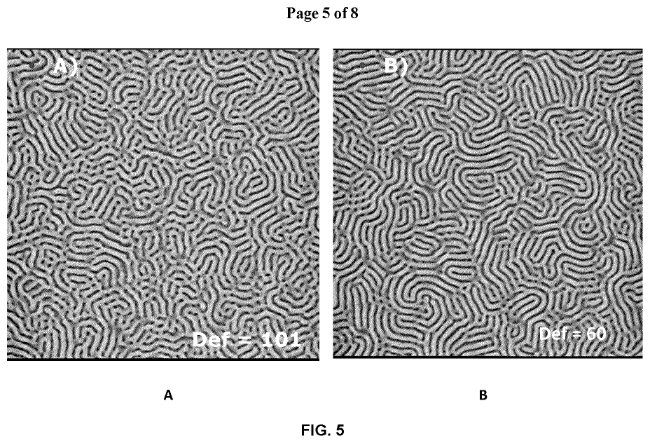

FIG. 5: 1FOV SEM images, Process conditions: Underlayer Polymer 1: 250° C./1 hour (N₂); EBR 2 min, spin dry, 110° C./1 min, FT=140 nm. Etching conditions: 02 (50 sccm):N₂ (50 sccm) for 30 sec, power=50 W, RIE=100, using Trion etcher. Defects counts measured using Hitachi software. A) Regular non-tethered ABA shows total defects of 101 and B) monotethered ABA shows defects of 60 with improved grain sizes.

FIG. 6: Kinetic enhancements multitethered C8S copolymerize with PS block. 1FOV SEM images, Process conditions: Underlayer Polymer 1: 250° C./1 hour (N₂); EBR 2 min, spin dry, 110 C/1 min, FT=140 nm. Etching conditions: 02 (50 sccm):N₂ (50 sccm) for 30 sec, power=50 W, RIE=100, using Trion etcher.

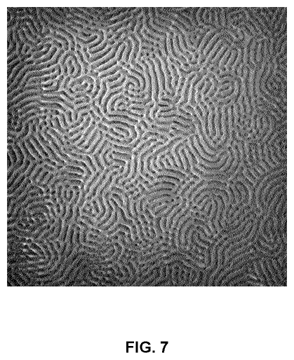

FIG. 7: Kinetic enhancements of ABA with copolymerized low T_{g} octyl styrene in PS block and copolymerized hexyl methacrylate in PMMA block 0.1 FOV SEM images, Process conditions: V: 250° C./1 hour (N₂); EBR 2 min, spin dry, 110° C./1 min, FT=140 nm. Etching conditions: 02 (50 sccm):N₂ (50 sccm) for 30 sec, power=50 W, RIE=100, using Trion etcher.

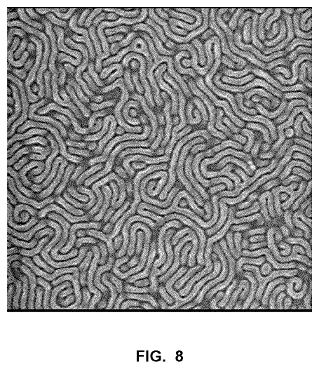

FIG. 8: Kinetic enhancements of ABA with isoprene at the junction of PS-PMMA. 1 FOV SEM images, Process conditions: V: 250° C./1 hour (N₂); EBR 2 min, spin dry, 110° C./1 min, FT=50 nm. Higher L₀ and much better grain sizes compared to regular ABA.

### SUMMARY OF THE INVENTION

Defect free assembly process of block copolymers requires high thermal energy and longer time. This difficulty limits application of directed self-assembly of block copolymer with large domain spacing and the use of triblock copolymer which doubles the molecular weight of diblock copolymers for multi-pitch applications in lithographic patterning. This invention relates to the synthesis of two kinetically enhanced block ABA triblock copolymer families.

The first ABA block copolymer family pertains to inventive ABA triblock copolymer with tethered group having general structure (1) as described herein, where A is an etchable polar block segment and B is a non-polar etch resistance block segment. Structure (1) as described herein covers the following general ABA architectures as shown in FIGS. 1 to 3. Novel mono- and multi-tethered ABA triblock copolymer derived from the following monomers as non-limiting examples styrene, substituted-styrene, methyl methacrylate, substituted methacrylate, diphenyl ethylene, and substituted-diphenyl ethylene synthesized using living anionic polymerization under appropriate condition. The substituent approach called tethered chemical configuration entails the tethering (a.k.a. attachment) of tethers which are either oligo polar or a oligo non-polar tether carbon-chain which may have different sub-side chain carbon and other hetero atoms. The tethers are situated either at the interface of the block chain segment, or as illustrated in either of FIG. 1 to FIG. 4.

FIG. 1 Schematically shown Block copolymer ABA Architectures in Structure (1) Family which are Mono-tethered with oligo flexible tethers at the interfaces and edges of ABA architectures.

FIG. 2: Block copolymer ABA Architectures in Structure (1) Family Multitethered with oligo flexible tethers bearing repeat unit copolymerized segment, and at interfaces and edges of ABA architectures a) Tethers on both A and B block, b) tethers only on B block, c) Tethers only on A block, d) short tethers at the interfaces and edges, e) long tethers at the interfaces and edges

FIG. 3: Block copolymer ABA Architectures in Structure (1) Family Multitethered with repeat units with -oligo flexible tethers copolymerized at the center of the middle block of ABA architectures

FIG. 4: Block copolymer ABA Architectures in Structure (6) Incorporation of low T_{g} Block Segments at the junctions of the ABA architectures which contains on non-polar B, polar blocks A or mixtures of these either specialty repeat units derived from monomers tethered with substitutions on either non-polar or polar blocks.

The second family having general structure (6) which contains substituents on the specialty monomers which are selected in such a way that they can impart kinetic enhancement for the block copolymer via absorbing thermal energy at high frequency flipping, reducing the overall glass transition temperature, subtly changing the chi parameters that does not alter surface energies of block copolymers and significantly the compatibility with conventional underlayer brush copolymer consisting of styrene and methyl methacrylate repeat units.

More importantly the present invention describes the synthesis of block copolymers in a particular sequence such as PMMA-b-PS-b-PMMA with mono and multitethered moieties of polar or non-polar nature as shown in the FIGS. 1 to 3. Examples of such structures are, P(M1-co-M2)-b-P(S1-co-S2)-b-P(M1-co-M2), PMMA-b-P(S1-co-S2)-b-PMMA, P(M1-co-M2)-b-PS-b-P(M1-co-M2), P(AlkylMA)-b-PMMA-b-P(Alkyl-S)-b-PS-b-P(Alkyl S)-b-PMMA-b-P(Alkyl MA), PMMA-b-PS-b-P(Alkyl S)-b-PS-b-PMMA and PMMA-b-PI-b-PS-b-PI-b-PMMA with target molecular weight exhibiting narrow molecular weight distribution (PDI<1.1), where S1 and M1 are styrene and methyl methacrylate monomer units, respectively. And S2 and M2 are substituted styrene, and substituted methyl methacrylate, respectively wherein the substitution being non-polar alkyl or polar ethylene oxide or dimethylsilyloxy containing pendent groups. These copolymers are made using living anionic polymerization in the presence of a bidirectional initiator. The said copolymers are used to self-assemble to generate periodic domain of compatible blocks within the di- or triblock copolymer into cylinders and lamellae morphologies depending on the volume composition of the polar to non-polar blocks. The invention also relates to the utilization of these copolymers as kinetically enhanced block copolymers for faster and easier self-assembly process to cover wide range of pitches to form line and space or contact-hole assemblies for applications in directed self-assembly for lithographic template generation under appropriate process conditions.

Another aspect of this invention is the method of using the above described compositions in a self-assembly process followed by pattern transfer of the self-assembled pattern into a substrate.

Another aspect still of this invention is the novel oligo diblock copolymer b-2) with block A-b) and block B-b) as described above.

Directing self-assembly (DSA) of polystyrene-b-polymethylmethacrylate (PS-b-PMMA) block copolymer is widely used as next generation lithography patterning. Microphase separation of diblock copolymer is used for feature size control in lithography. The widely used diblock copolymer such as PS-b-PMMA can produce mono and unidirectional feature sizes in thin film morphology with appropriate underlayer or prepattern for DSA application. However, if one wants a multi pitch feature sizes from a single diblock copolymer formulation, it is not possible with current PS-b-PMMA block copolymers for extended pitches. This is because, triblock copolymers of PMMA-b-PS-b-PMMA (ABA) with L₀ 50 nm have been shown to produce multi pitch DSA from 50 nm to 80 nm which is very important for IC industries for design flexibility (FIG. 3 on page 5543 of Ji et al ACS NANO, Ji et al, VOL. 6, NO. 6, pp 5440-5448). This type of ABA Triblock copolymers can produce defect free DSA at bend angle 45, 90 and 135 deg (FIG. 6 on page 5445 of Ji et al ACS NANO, Ji et al, VOL. 6, NO. 6, pp 5440-5448). However, a problem to be solved is that the assembly kinetics This type of ABA Triblock copolymers is 3 times slower than AB type diblock copolymers due to the higher M_{w} as well as changes in the fractions of loop and bridge formation of the middle PS block. It requires about 36 hours of annealing to get defect free DSA on multi pitch, which is not viable for industrial manufacturing. Hence, the development of novel triblock copolymers that can provide a faster kinetics and can orient in conventional underlayers for DSA is very important.

Herein we disclose our development of a series of novel modified ABA triblock copolymers using traditional and specialty monomers as comonomers and with long or short tethers of which are respectively 18 or 6 atoms in length, which are non-polar or polar situated at the interfaces and at the ends of the blocks for better mobility and faster kinetics by reducing the overall glass transition temperature. We also developed series of multilettered copolymerized ABA with low T_{g} comonomers in either at Polystryrene (PS) block or in poly(methyl methacrylate) (PMMA) block or in both PS and PMMA blocks. Some examples are, P(M1-co-M2)-b-P(S1-co-S2)-b-P(M1-co-M2), PMMA-b-P(S1-co-S2)-b-PMMA, P(M1-co-M2)-b-PS-b-P(M1-co-M2), P(AlkylMA)-b-PMMA-b-P(Alkyl-S)-b-PS-b-P(Alkyl S)-b-PMMA-b-P(Alkyl MA), PMMA-b-PS-b-P(Alkyl S)-b-PS-b-PMMA and PMMA-b-PI-b-PS-b-PI-b-PMMA with target molecular weight exhibiting narrow molecular weight distribution (PDI<1.1), where S1 and M1 are styrene and methyl methacrylate monomer units, respectively. And S2 and M2 are substituted styrene, and substituted methyl methacrylate, respectively wherein the substitution being non-polar alkyl or polar ethylene oxide or dimethylsilyoxy containing pendent groups.

Newly developed all ABA's were tested for finger-print morphology over neutral underlayer brushed substrate on SiOx. In order to evaluate the novel triblock copolymers, we also developed thick film finger-print network defects analysis method wherein we coat these block copolymer at 2 and 3×L₀ and partially dry etch (with oxygen plasma) to identify and count network defects in the bulk of the film. This results are compared with regular non-tethered ABA block copolymers which showed very less defects and faster kinetics for modified with mono-, multi-tethered ABA block copolymers either at the interface and edges or copolymerized with specialty substituted monomer at less than 20% in order not to affect significantly the chi parameter of the new block copolymer. As the synthesis is accomplished via living anionic copolymerization, the described triblock ABA copolymer exhibits a narrow molecular weight distribution (M_{w}/Mₙ<1.1) and works with normal underlayers that are suitable for PS-b-PMMA DSA.

One aspect of this invention is a block copolymer having structure (1), wherein A segment is a polar block copolymer segment comprised either alkyl 2-methylenealkanoate derived repeating units, lactone derived repeat units, oxirane derived repeat units, oxetane derived repeating units, or cyclic carbonate derived repeat units; L is either a direct valence bond or a linking moiety derived from a 1,1-diarylethene; B segment is anon-polar block copolymer segment comprised of styrenic repeat unit, E are end groups selected from H, an alkyl, a carbonylalkyl (—C═O-alkyl), a carbonyloxyalkyl (—C═O—O-alkyl, and an alkyl 2-arylacrylate derived end group (—CH₂—CH(Aryl)(C(═O))—O-alkyl).

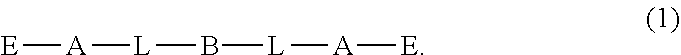

Further, the block copolymer of structure (1) is multi-tethered with oligo flexible tethered groups which are selected from oligo linear alkylene tethered group, oligo ether tethered groups, and oligo dialkyl siloxane tethered groups.

Further, these oligo flexible tethered groups are multi-tethered at positions selected from the following placements in the polymer block copolymer of structure (1):
said oligo flexible tethered groups are only present on segments A and are either randomly located along this segment on some of its repeat units or present on each of its repeat units.
Said oligo flexible tethered groups are only present on segment B and are either randomly located along this segment on some of its repeat units or present on each of its repeat units,
Said oligo flexible tethered groups are present on both segments A and segments B and are either randomly located along these segments on only some of its repeat units or present on each of their repeat units,
Said oligo flexible tethered group are present on both E end groups, when these are an alkyl or an alkyl 2-arylacrylate derived end group (—CH₂—CH(Aryl)(C(═O))—O-alkyl), said oligo flexible tethered groups are present on both L when L is a linking moiety derived from a 1,1-diarylethene,
said oligo flexible tethered groups are present in the center of the B segment; and
said oligo flexible tethered groups are present on at least one of A segments, B segments, L, (when L is said linking moiety), and end groups E.

Further, the block copolymer of structure (1) has a polydispersity ranging from 1 to about 1.09.

Another aspect of this invention is a block copolymer of structure (6), wherein A₁ is a polar block copolymer segment which has a T_{g} from about 50° C. to about 100° C., comprised of either alkyl 2-methylenealkanoate derived repeating units, lactone derived repeat units, oxirane derived repeat units, oxetane derived repeating units, or cyclic carbonate derived repeat units; and B1 is a styrenic block copolymer segment, which has a T_{g} from about 50° C. and to about 100° C. Also, in this embodiment B₂ is block copolymer segment with a T_{g} ranging from about −5° C. to about −50° C., which comprises repeat units derived from either an olefin selected from the group consisting of an alkene, an alkadiene, and an alkatriene, or a from mixture of at two different olefins selected from this group. Further in this embodiment L₁ is either a direct valence bond or a linking moiety derived from a 1,1-diarylethene and E₁ are end groups selected from H, an alkyl, a carbonylalkyl (—C═O-alkyl), a carbonyloxyalkyl (—C═O—O-alkyl, and an alkyl 2-arylacrylate derived end group (—CH₂—CH(Aryl)(C(═O))—O-alkyl) and said block copolymer has a polydispersity ranging from 1 to about 1.09.

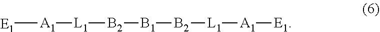

Another aspect of this invention are compositions comprising the inventive block copolymer of structure (1), or the inventive block copolymer of structure (6) and a spin casting solvent.

Another aspect of this invention is the method of using the above described compositions in a self-assembly process followed by pattern transfer of the self-assembled pattern into a substrate.

Another aspect of this invention is a compound of structure (C1), wherein R_{1b}, R_{1c}, R_{2c} and R_{2c} are individually selected from H, a halide, a C-1 to C-4 alkyl, a C-1 to C-4 alkyloxy and an oligo flexible tethered groups, wherein at least one of R_{1b}, R_{2b}, R_{1c}, and R_{2c} is an oligo flexible tethered group and R_{3b}, R_{3c}, R_{4b}, R_{4c}, R_{5b} and R_{5c} are individually selected from H, a halide, a C-1 to C-4 alkyl, and a C-1 to C-4 alkyloxy;

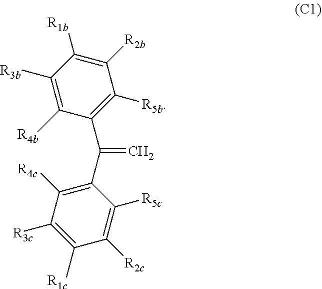

### DETAILED DESCRIPTION OF THE INVENTION

It is to be understood that both the foregoing general description and the following detailed description are illustrative and explanatory, and are not restrictive of the subject matter, as claimed. In this application, the use of the singular includes the plural, the word “a” or “an” means “at least one”, and the use of “or” means “and/or”, unless specifically stated otherwise. Furthermore, the use of the term “including,” as well as other forms such as “includes” and “included”, is not limiting. Also, terms such as “element” or “component” encompass both elements and components comprising one unit and elements or components that comprise more than one unit, unless specifically stated otherwise. As used herein, the conjunction “and” is intended to be inclusive and the conjunction “or” is not intended to be exclusive unless otherwise indicated. For example, the phrase “or, alternatively” is intended to be exclusive. As used herein, the term “and/or” refers to any combination of the foregoing elements including using a single element.

The term “tethered,” refers to the attachment of an oligo flexible group (a.k.a. oligo tethers) to different portions of the inventive block copolymer having structure (1), as defined herein.

L₀ is the natural pitch of assembled block copolymer which tends to be proportional to the size of copolymer.

The term C-1 to C-4 alkyl embodies methyl and C-2 to C-4 linear alkyls and C-3 to C-4 branched alkyl moieties, for example as follows: methyl(—CH₃), ethyl (—CH₂—CH₃), n-propyl (—CH₂—CH₂—CH₃), isopropyl (—CH(CH₃)₂, n-butyl (—CH₂—CH₂—CH₂—CH₃), tert-butyl (—C(CH₃)₃), isobutyl (CH₂—CH(CH₃)₂, 2-butyl (—CH(CH₃)CH₂—CH₃). Similarly, the term C-1 to C-8 alkyl embodies methyl C-2 to C-8 linear, C-3 to C-8 branched alkyls, C-4 to C-8 cycloalkyls (e.g. cyclopentyl, cyclohexyl etc) or C-5-C-8 alkylenecycloalkyls (e.g. —CH₂-cyclohexyl, CH₂—CH₂-cyclopentyl etc.

The term C-2 to C-5 alkylene embodies C-2 to C-5 linear alkylene moieties (e.g. ethylene, propylene etc.) and C-3 to C-5 branched alkylene moieties (e.g. —CH(CH₃)—, —CH(CH₃)—CH₂—, etc.).

Di-block and triblock copolymers of styrenic and alkyl 2-methylenealkanoate derived repeat unit moieties useful as components in the inventive compositions described herein may be made by a variety of methods, such as anionic polymerization, atom transfer radical polymerization (ATRP), Reversible addition-fragmentation chain transfer (RAFT) polymerization, living radical polymerization and the like (Macromolecules 2019, 52, 2987-2994; Macromol. Rapid Commun. 2018, 39, 1800479; A. Deiter Shluter et al Synthesis of Polymers, 2014, Volume 1, p 315; Encyclopedia of Polymer Science and Technology, 2014, Vol 7, p 625.)

The random copolymer poly(styrene-co-methyl methacrylate) is abbreviated as “P(S-co-MMA),” and the oligomeric version of this materials is abbreviated oligo(S-co-MMA). Similarly the block copolymer poly(styrene-block-methyl methacrylate) is abbreviated as P(S-b-MMA), while the oligomer of this material is abbreviated as oligo(S-b-MMA). The oligomer oligo(styrene-co-p-octylstyrene)-block-(methyl methacrylate-co-di(ethylene glycol) methyl ether methacrylate) uses the same abbreviations to designate random an block copolymer elements, specifically oligo(S-co-p-OS)-b-P(MMA-co-DEGMEMA), in which S=styrene, p-OS=para-octylstyrene, MMA=methacrylate, DEGMEMA=di(ethylene glycol) methyl ether methacrylate designate the repeat units in this block copolymer whose two blocks are random copolymers.

FOV is the abbreviation for field of view for top down scanning electron micrographs (SEM) for the SEM FIGs. in this application. “L/S,” is an abbreviation for line and space lithographic features.

The term alkyl 2-methylenealkanoate (alkyl-O—(C═O)—C(alkyl)=CH₂), refers to alkyl esters of a 2-methylenealkanoate, wherein said 2-methylenealkanoate may incorporate up to 11 carbon atoms, and said alkyl an alkyl 2-methylenealkanoate may incorporate up to 8 carbon atoms, selected from methyl, linear alkyls, branched alkyls and cyclic alkyls. The following structures give a general structure for such alkyl 2-methylenealkanoate, where Ralka and Ralke independently are selected from C-1 to C-8 alkyl groups and show non-limiting examples of alkyl 2-methylenealkanoates falling within this scope.

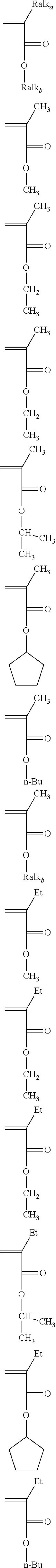

The term styrenic as used herein, unless otherwise indicated, encompasses repeat units derived from styrene derivative generally for examples ones derived from styrene derivatives having the following structure, wherein Xsty moiety is H or a C-1 to C-4 alkyl and the Rsty moiety is H, C-1 to C-5 alkyl, a halide, a C-1 to C-5 alkyloxy or an oligo flexible tethered group, is the number of Rsty substituents and is 1 or 2.

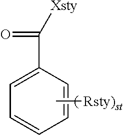

The term 1,1-diarylethene as used herein, unless otherwise indicated, encompasses a moiety derived from ethene which has two substituents at the 1 position which are aryl moieties as shown as follows, where Aryl₁ and Aryl₂ are aryl substituent selected from phenyl, or substituted phenyl, and if the substituents is present in either, or both Aryl₁ and Aryl₂ these substituents are independently selected from a C-1 to C-5 alkyl, a halide, a C-1 to C-5 alkyloxy and an oligo flexible tethered group.

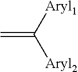

The term “alkyl 2-arylacrylate derived end group,” described with the generic structure (—CH₂—CH(Aryl)(C(═O))—O-alkyl) unless otherwise indicated, is defined in more detail in the general structure below where * indicates the attachment point to the end of a block copolymer chain; Aryl₃ is an aryl substituent selected from phenyl, or substituted phenyl, and if a substituents is present in either, where this substituents are independently selected from a C-1 to C-5 alkyl, a halide, a C-1 to C-5 alkyloxy and an oligo flexible tethered group, and further where alkyl₃ is an unsubstituted alkyl C-1 to C-5 alkyl or a C-1 to C-5 alkyl substituted with an oligo flexible tethered group. This end group structure may be derived, as an illustrative example, by a 2-arylacrylate alkyl ester reacting at the CH₂ olefinic moiety with a living anion at the end of a polymeric chain forming a CH⁻ anion which is then terminated by protonation.

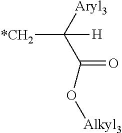

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature references and similar materials defines a term in a manner that contradicts the definition of that term in this application, this application controls.

Unless otherwise indicated, “alkyl” refers to hydrocarbon groups which can be linear, branched (e.g., methyl, ethyl, propyl, isopropyl, tert-butyl and the like) or cyclic (e.g., cyclohexyl, cyclopropyl, cyclopentyl and the like) multicyclic (e.g., norbornyl, adamantly and the like). These alkyl moieties may be substituted or unsubstituted as described below. The term “alkyl” refers to such moieties with C-1 to C-8 carbons. It is understood that for structural reasons linear alkyls start with C-1, while branched alkyls and linear start with C-3 and multicyclic alkyls start with C-5. Moreover, it is further understood that moieties derived from alkyls described below, such as alkyloxy and perfluoroalkyl, have the same carbon number ranges unless otherwise indicated. If the length of the alkyl group is specified as other than described above, the above described definition of alkyl still stands with respect to it encompassing all types of alkyl moieties as described above and that the structural consideration with regards to minimum number of carbons for a given type of alkyl group still apply.

Alkyloxy (a.k.a. Alkoxy) refers to an alkyl group on which is attached through an oxy (—O—) moiety (e.g. methoxy, ethoxy, propoxy, butoxy, 1,2-isopropoxy, cyclopentyloxy cyclohexyloxy and the like). These alkyloxy moieties may be substituted or unsubstituted as described below.

Halo or halide refers to a halogen, F, Cl, Br or I which is linked by one bond to an organic moiety.

As used herein the term lactone encompasses both mono-lactones (e.g., caprolactone) and di-lactones (e.g., lactide).

Haloalkyl refers to a linear, cyclic or branched saturated alkyl group such as defined above in which at least one of the hydrogens has been replaced by a halide selected from the group of F, Cl, Br, I or mixture of these if more than one halo moiety is present. Fluoroalkyls are a specific subgroup of these moieties.

Perfluoroalkyl refers to a linear, cyclic or branched saturated alkyl group as defined above in which the hydrogens have all been replaced by fluorine (e.g., trifluoromethyl, pefluoroethyl, prefluoroisopropyl, perfluorocyclohexyl and the like).

The term oligo flexible tethered groups, as used in describing different embodiments of inventive polymers or compounds described herein, refers to a grouping of moieties which includes oligo linear alkylene tethered groups, oligo ether tethered groups and oligo dialkyl siloxane tethered groups.

The term oligo linear alkylene tethered group in the different embodiments of inventive polymers or compounds, described herein, refers in the widest embodiments to groups having the following general structures: —X1-(CH₂)ₐ—CH₃, where a is 6 to 18. and X1 is selected from a direct valence bond, a linear C-1 to C-4 alkylene spacer, —O—, —CH₂—O—, —O—(C═O)—, —C═O—O—, C═O, —CH₂—O—(C═O)—, —S—, —SO₂—, —SO—. In one embodiment, X1 is a direct valence bond. In another embodiment, X1 is a linear C-1 to C-4 alkylene spacer. In another embodiment X1 is —O—. in still another it is —CH₂—O; in still another X1 is —O—(C═O)—. In another embodiment X1 is —C═O—O—. In another embodiment X1 is a carbonyl (C═O). In another embodiment X1 is —CH₂—O—(C═O)—. In another embodiment X1 is —S—. In another embodiment X1 is —SO₂—. In another embodiment X1 is —SO—. More specific types of these groups are —O—(CH₂)ₐ—CH₃, or —CH₂—O—(CH₂)ₐ—CH₃ wherein a is 6 to 19. In more specific embodiments —O—(CH₂)ₐ—CH₃, or —CH₂—O—(CH₂)ₐ—CH₃ have a equal from 7 to 19. In a still more selective embodiment O—(CH₂)ₐ—CH₃, or —CH₂—O—(CH₂)ₐ—CH₃ have a equal from 7 to 10. In a still more selective embodiment O—(CH₂)ₐ—CH₃, or —CH₂—O—(CH₂)ₐ—CH₃ have a equal from 8-9. In a still more selective embodiment O—(CH₂)ₐ—CH₃, or —CH₂—O—(CH₂)ₐ—CH₃ have a equal to 8. In another more specific embodiments —O—(CH₂)ₐ—CH₃, or —CH₂—O—(CH₂)ₐ—CH₃ have a equal from 7 to 14. In a still more selective embodiment O—(CH₂)ₐ—CH₃, or —CH₂—O—(CH₂)ₐ—CH₃ have a equal from 7 to 13. In a still more selective embodiment O—(CH₂)ₐ—CH₃, or —CH₂—O—(CH₂)ₐ—CH₃ have a equal from 8-13. In a still more selective embodiment O—(CH₂)ₐ—CH₃, or —CH₂—O—(CH₂)ₐ—CH₃ have a equal to 13. In another more specific embodiments —O—(CH₂)ₐ—CH₃, or —CH₂—O—(CH₂)ₐ—CH₃ have a equal from 7 to 19. In a still more selective embodiment O—(CH₂)ₐ—CH₃, or —CH₂—O—(CH₂)ₐ—CH₃ have a equal from 8 to 19. In a still more selective embodiment O—(CH₂)ₐ—CH₃, or —CH₂—O—(CH₂)ₐ—CH₃ have a equal from 9-19. In a still more selective embodiment O—(CH₂)ₐ—CH₃, or —CH₂—O—(CH₂)ₐ—CH₃ equal from 10 to 19. In a still more selective embodiment O—(CH₂)ₐ—CH₃, or —CH₂—O—(CH₂)ₐ—CH₃ equal from 11 to 19. In a still more selective embodiment O—(CH₂)ₐ—CH₃, or —CH₂—O—(CH₂)ₐ—CH₃ equal from 12 to 19. In a still more selective embodiment O—(CH₂)ₐ—CH₃, or —CH₂—O—(CH₂)ₐ—CH₃ equal from 13 to 19. In a still more selective embodiment O—(CH₂)ₐ—CH₃, or —CH₂—O—(CH₂)ₐ—CH₃ equal from 13 to 19. In a still more selective embodiment O—(CH₂)ₐ—CH₃, or —CH₂—O—(CH₂)ₐ—CH₃ equal from 14 to 19. In a still more selective embodiment O—(CH₂)ₐ—CH₃, or —CH₂—O—(CH₂)ₐ—CH₃ equal from 15 to 19. In a still more selective embodiment O—(CH₂)ₐ—CH₃, or —CH₂—O—(CH₂)ₐ—CH₃ equal from 16 to 19. In a still more selective embodiment O—(CH₂)ₐ—CH₃, or —CH₂—O—(CH₂)ₐ—CH₃ equal from 17 to 19. In a still more selective embodiment O—(CH₂)ₐ—CH₃, or —CH₂—O—(CH₂)ₐ—CH₃ equal from 18 to 19. In a still more selective embodiment O—(CH₂)ₐ—CH₃, or —CH₂—O—(CH₂)ₐ—CH₃ a equals 18. These linear alkylene tethered group may either be unsubstituted or substituted with a C-1 to C-8 alkyl group forming a branching point.

The term oligo ether tethered group in the different embodiments of inventive polymers or compounds, described herein, refers to material having the following general structures: —O—[(CH₂)ₑ—O-]ₑ₂-(CH₂)ₑ₃—H, —(CH₂)ₑ₄—O—(CH₂)ₑ—O—(CH₂)ₑ₂—(CH₂)ₑ₃—H, wherein independently e is from 2 to 8, e2 is from 2 to 8, e3 from is 1 to 8, and e4 is from 1 to 8. In one specific embodiment it is —O—(CH₂—CH₂—O)ₑ₂—(CH₂)ₑ₃—H; in a more specific aspect of this embodiment it is O—(CH₂—CH₂—O)ₑ₂—(CH₃); in a more specific aspect of this embodiment it is —CH₂—O—(CH₂—CH₂—O)₄—CH₃; in yet another more specific embodiment it is O—(CH₂—CH₂—O)₄—CH₃. In another more specific embodiment it is —CH₂—O—(CH₂—CH₂—O)ₑ₂—(CH₂)ₑ₃—H. In another more specific embodiment it is —CH₂—O—(CH₂—CH₂—O)ₑ₂—CH₃, in another more specific aspect of this embodiment it is CH₂—O—(CH₂—CH₂—O)₄—CH₃, another more specific aspect of this embodiment it is CH₂—O—(CH₂—CH₂—O)₂—CH₃. These oligo ethers tethered group may either be unsubstituted or substituted with a C-1 to C-8 alkyl group forming a branching point.

The term oligo dialkyl siloxane tethered group present in the different embodiments of inventive polymers or compounds, described herein, refers to groups having the following general structures —X2-[Si(alkyl)₂-O]ₛ—Si(alkyl)₃, where s is from 6 to 18 and the alkyl moiety is a C-1 to C-8 alkyl and X2 is a direct valence bond, or a C-1 to C-8 linear alkylene spacer, or —O—. In a more specific aspect of this embodiment it is —O—[Si(alkyl)₂-O]ₛ—Si(alkyl)₃, in a more specific aspect of this embodiment it is —O—[Si(CH₃)₂—O]ₛ—Si(CH₃)₃. In another more specific aspect of this embodiment it is —CH₂—O—[Si(alkyl)₂-O]ₛ—Si(alkyl)₃, in a more specific aspect of this embodiment it is —CH₂—O—[Si(CH₃)₂—O]ₛ—Si(CH₃)₃.

One aspect of this invention is a block copolymer having structure (1), wherein A segment is a polar block copolymer segment comprised either alkyl 2-methylenealkanoate derived repeating units, lactone derived repeat units, oxirane derived repeat units, oxetane derived repeating units, or cyclic carbonate derived repeat units; L is either a direct valence bond or a linking moiety derived from a 1,1-diarylethene; B segment is a non-polar block copolymer segment comprised of styrenic repeat unit, E are end groups selected from H, an alkyl, a carbonylalkyl (—C═O-alkyl), a carbonyloxyalkyl (—C═O—O-alkyl, and an alkyl 2-arylacrylate derived end group (—CH₂—CH(Aryl)(C(═O))—O-alkyl).

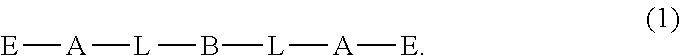

Further, the block copolymer of structure (1) is multi-tethered with oligo flexible tethered groups which are selected from oligo linear alkylene tethered group, oligo ether tethered groups, and oligo dialkyl siloxane tethered groups.

Further, these oligo flexible tethered groups are multi-tethered at positions selected from the following placements in the polymer block copolymer of structure (1): Said oligo flexible tethered groups are only present on segments A and are either randomly located along this segment on some of its repeat units or present on each of its repeat units.
Said oligo flexible tethered groups are only present on segment B and are either randomly located along this segment on some of its repeat units or present on each of its repeat units.
Said oligo flexible tethered groups are present on both segments A and segments B and are either randomly located along these segments on only some of its repeat units or present on each of their repeat units,
Said oligo flexible tethered group are present on both E end groups, when these are an alkyl or an alkyl 2-arylacrylate derived end group (—CH₂—CH(Aryl)(C(═O))—O-alkyl).
said oligo flexible tethered groups are present on both L when L is a linking moiety derived from a 1,1-diarylethene.
said oligo flexible tethered groups are present in the center of the B segment.
said oligo flexible tethered groups are present on at least one of A segments, B segments, L, (when L is said linking moiety), and end groups E

Further, said block copolymer has a polydispersity ranging from 1 to about 1.09. In another aspect of this embodiment it ranges from 1 to about 1.08; in yet another embodiment it ranges from 1 to about 1.07; in still another embodiment it ranges from 1 to about 1.06, in still another embodiment it ranges from 1 to about 1.05; in still another embodiment it ranges from 1 to about 1.03; in still another embodiment it ranges from 1 to about 1.02; in still another embodiment it ranges from 1 to about 1.01; and in one embodiment it has a polydispersity of 1.

In another aspect of the block copolymer of structure (1), described herein, said polar block copolymer segment A is comprised of repeat units derived from a lactone. In one aspect of this embodiment said lactone is a mono-lactone such as caprolactone and the like. In another aspect of this embodiment said lactone is di-lactone such as lactide and the like.

In another aspect of the block copolymer of structure (1), described herein, said polar block copolymer segment A₁ is comprised of repeat units derived from an oxirane. In one aspect of this embodiment said repeat units are derived from oxetane. In another aspect of this embodiment said repeat units are derived from a substituted oxetane. In another aspect of this embodiment they are derived from an alkyl substituted oxetane.

In another aspect of the block copolymer of structure (1), described herein, said polar block copolymer segment A₁ is comprised of repeat units derived from an oxirane. In one aspect of this embodiment said repeat unit is derived from oxirane. In another aspect they are derived from a substituted oxirane. In yet another aspect of this embodiment they are derived from an alkyl substituted oxirane. In one aspect of this embodiment they are derived from 2-methyloxirane.

In another aspect of the block copolymer of structure (1), described herein, said polar block copolymer segment A₁ is comprised of repeat units derived from a cyclic carbonate. In one aspect of this embodiment, they are derived from 1,3-dioxolan-2-one. In another aspect of this embodiment, they are derived from a substituted 1,3-dioxolan-2-one. In yet another aspect of this embodiment it is derived from a 2-alkyl-dioxolan-2-one. In still another aspect of this embodiment they are derived from 2-methyl-dioxolan-2-one.

In another aspect of the block copolymer of structure (1), described herein, said polar block copolymer segment A is comprised of alkyl 2-methylenealkanoate derived repeating units. In one aspect of this embodiment said alkyl 2-methylenealkanoate is selected from ones having any one the following structures:

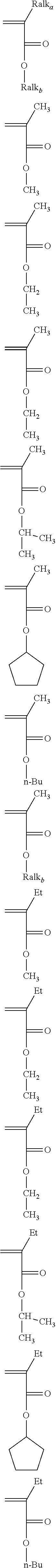

In another aspect of the block copolymer of structure (1), described herein, said polar block copolymer segment A segment has a M_{w} between about 20,000 and about 200,000, and said non-polar styrenic block copolymer segment B has a M_{w} between 20,000 and about 200,000. In another aspect of this embodiment said polar block copolymer segment A segment has a M_{w} between about 30,000 and about 170,000 and said non-polar styrenic block copolymer segment B has a M_{w} between 40,000 and about 160,000. In another aspect of this embodiment said polar block copolymer segment A segment has a M_{w} between about 30,000 and about 167,000 and said non-polar styrenic block copolymer segment B has a M_{w} between 40,000 and about 150,000.

In another aspect of the block copolymer of structure (1), described herein, said polar block copolymer segment A segment has a Mₙ between about 20,000 and about 200,000, and said non-polar styrenic block copolymer segment B has a Mn between 20,000 and about 200,000. In another aspect of this embodiment said polar block copolymer segment A segment has a Mₙ between about 25,000 and about 170,000 and said non-polar styrenic block copolymer segment B has a Mn between 30,000 and about 160,000. In another aspect of this embodiment said polar block copolymer segment A segment has a Mₙ between about 28,000 and about 155,000 and said non-polar styrenic block copolymer segment B has a Mn between 40,000 and about 135,000.

In another aspect of the block copolymer of structure (1), described herein, L is a direct valence bond. In another aspect L is a linking moiety derived from a 1,1-diarylethene.

In another aspect of the block copolymer of structure (1), described herein, E is either H or an alkyl. In another aspect of this embodiment it is H. In another aspect of this embodiment, it is an alkyl group.

In another aspect of the block copolymer of structure (1), described herein, E is an end group derived from an alkyl-2-arylacrylate.

In another aspect of the block copolymer of structure (1), described herein, E is a carbonylalkyl (—C═O-alkyl), or a carbonyloxyalkyl (—C═O—O-alkyl). In another aspect of this embodiment, it is a carbonylalkyl (—C═O-alkyl). In yet another aspect of this embodiment it is a carbonyloxyalkyl (—C═O—O-alkyl.

In another aspect of the block copolymer of structure (1), it has structure (2), wherein R₁, R₂, R₃, R₄, R₅, R₆, and R₇, are individually selected from H, a C-1 to C-5 alkyl, a halide, a C-1 to C-5 alkyloxy and said oligo flexible tethered groups wherein further at least one of R₁, R₂, R₃, R₄, R₅, R₆, and R₇, is selected from said oligo flexible tethered groups and n is the number of repeat units. In yet another aspect of this embodiment, said oligo flexible tethered group if present on an aromatic ring is at a para or meta position, in another aspect of this embodiment it is present at a meta position in yet another embodiment it is present at a para position.

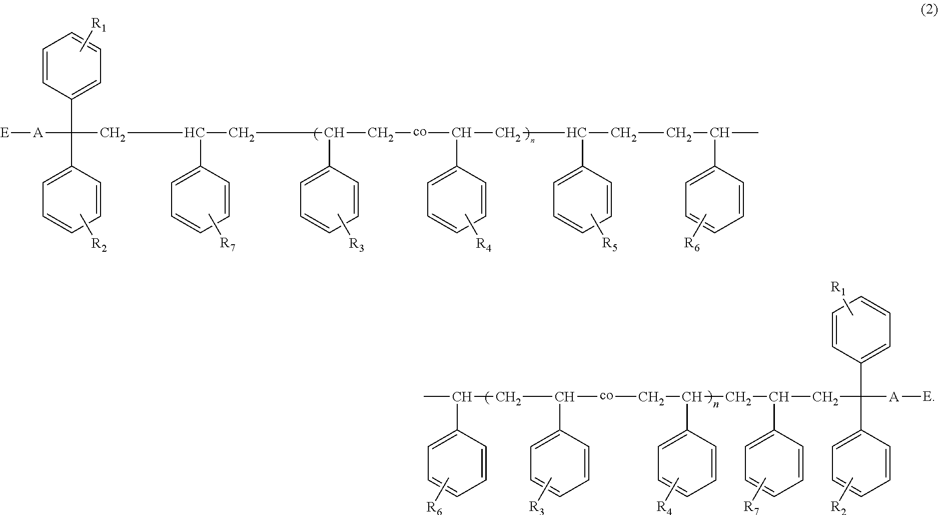

In another aspect of the block copolymer of structure (1), it has structure (3), wherein R₁, and R₂, are individually selected from H, a C-1 to C-5 alkyl, a halide, a C-1 to C-5 alkyloxy and said oligo flexible tethered groups, R₈, and R₉, are individually selected from a C-1 to C-5 alkyl, and said oligo flexible tethered groups, R₁₀ is H or a C-1 to C-5 alkyl, R₁₁ is H, C-1 to C-5 alkyl, a halide or a C-1 to C-5 alkyloxy; wherein further at least one of R₁, R₂, R₈, and R₉, is selected from said oligo flexible tethered groups, and n1 is the number of repeat units. In another aspect of the block copolymer of structure (1), it has structure (2), wherein R₁, R₂, R₃, R₄, R₅, R₆, and R₇, are individually selected from H, a C-1 to C-5 alkyl, a halide, a C-1 to C-5 alkyloxy and said oligo flexible tethered groups wherein further at least one of R₁, R₂, R₃, R₄, R₅, R₆, and R₇, is selected from said oligo flexible tethered groups and n is the number of repeat units. In another aspect of this embodiment groups, R₁ and R₂ are individually selected from H, a C-1 to C-5 alkyl, a halide, a C-1 to C-5 alkyloxy. In another aspect of this embodiment, R₁ and R₂ are individually selected from H, a C-1 to C-5 alkyl, a halide, a C-1 to C-5 alkyloxy. In yet another aspect of this embodiment, R₈ is selected from said oligo flexible tethered groups, R₁ and R₂ are individually selected from H, a C-1 to C-5 alkyl, a halide, a C-1 to C-5 alkyloxy. In still another aspect of this embodiment said oligo flexible tethered group is an oligo linear alkylene tethered group. In yet another aspect of this embodiment said oligo flexible tethered group is an oligo ether tethered group. In still another aspect of this embodiment said oligo flexible tethered group is an oligo dialkyl siloxane tethered group.

In another aspect of the block copolymer of structure (3), R₉ and R₈ are individually selected from said oligo flexible tethered groups, R₁ and R₂ are individually selected from H, a C-1 to C-5 alkyl, a halide, and a C-1 to C-5 alkyloxy. In another aspect of this embodiment, said oligo flexible tethered group is an oligo linear alkylene tethered group. In yet another aspect of this embodiment said oligo flexible tethered group is an oligo ether tethered group. In still another aspect of this embodiment, said oligo flexible tethered group is an oligo dialkyl siloxane tethered group.

In another aspect of the block copolymer of structure (3), R₁, R₂ and R₈ are individually selected from said oligo flexible tethered groups. In another aspect of this embodiment, said oligo flexible tethered groups is an oligo linear alkylene tethered group. In yet another aspect of this embodiment, said oligo flexible tethered group is an oligo ether tethered group. In still another aspect of this embodiment said oligo flexible tethered group is an oligo dialkyl siloxane tethered group. In yet another aspect of this embodiment, said oligo flexible tethered group if present on an aromatic ring is at a para or meta position, in another aspect of this embodiment it is present at a meta position in yet another embodiment it is present at a para position.

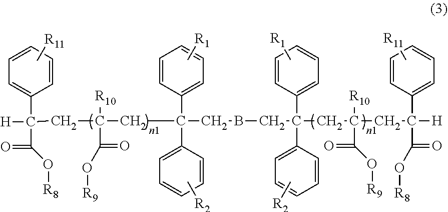

In another aspect of the block copolymer of structure (1), described herein, it has structure (4), wherein R₁, and R₂, are individually selected from H, a C-1 to C-5 alkyl, a halide, a C-1 to C-5 alkyloxy and said oligo flexible tethered groups, R₉ₐ and R_{9b} are individually selected from a C-1 to C-5 alkyl, and said oligo flexible tethered groups, R₁₀ₐ and R_{10b} are individually selected from H or a C-1 to C-5 alkyl, R₁₂ is H or a C-1 to C-5 alkyl, and further wherein at least one of R₁, R₂, R₉ₐ and R_{9b} is selected from said oligo flexible tethered groups and n2 and n3 are the number of repeat units. In another aspect of this embodiment R_{5b} is selected from said oligo flexible tethered group, R₉ₐ is a C-1 to C-5 alkyl, R₁, and R₂, are individually selected from H, a C-1 to C-5 alkyl, a halide, and a C-1 to C-5 alkyloxy. In another aspect of this embodiment, said oligo flexible tethered group is an oligo linear alkylene tethered group. In yet another aspect of this embodiment said oligo flexible tethered group is an oligo ether tethered group. In still another aspect of this embodiment said oligo flexible tethered group is an oligo dialkyl siloxane tethered group.

In another embodiment of the block copolymer of structure (4), described herein, R₉ₐ and R_{9b} are individually selected from a C-1 to C-5 alkyl, R₁, and R₂, are individually selected from H, a C-1 to C-5 alkyl, a halide, and a C-1 to C-5 alkyloxy and said oligo flexible tethered group is an oligo ether tethered group, wherein further as at least one of R₁, and R₂ is selected from said oligo flexible tethered group. In another aspect of this embodiment said oligo flexible tethered group is an oligo linear alkylene tethered group. In yet another aspect of this embodiment, said oligo flexible tethered group is an oligo ether tethered group. In still another aspect of this embodiment, said oligo flexible tethered group is an oligo dialkyl siloxane tethered group. In another aspect of this embodiment said oligo dialkyl siloxane tethered groups when present on an aromatic ring are present at a para or meta position.

In another embodiment of the block copolymer of structure (4), described herein, R₉ₐ and R_{9b} are individually selected from said oligo flexible tethered group, and R₁, and R₂, are individually selected from H, a C-1 to C-5 alkyl, a halide, and a C-1 to C-5 alkyloxy. In another aspect of this embodiment, said oligo flexible tethered group is an oligo linear alkylene tethered group. In yet another aspect of this embodiment, said oligo flexible tethered group is an oligo ether tethered group. In still another aspect of this embodiment, said oligo flexible tethered group is an oligo dialkyl siloxane tethered group. In yet another aspect of this embodiment, said oligo flexible tethered group if present on an aromatic ring is at a para or meta position, in another aspect of this embodiment it is present at a meta position in yet another embodiment it is present at a para position.

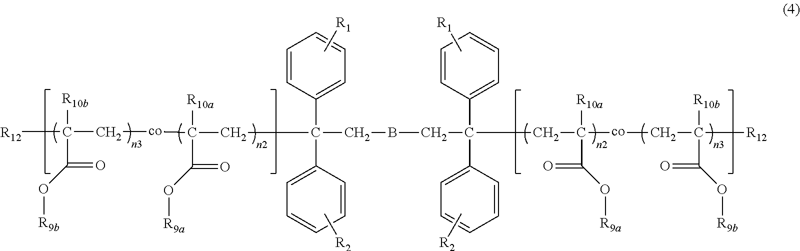

In another aspect of the block copolymer of structure (1), described herein, it has structure (5), wherein R₃, R₄, R₅, R₆, and R₇, are individually selected from H, a C-1 to C-5 alkyl, a halide, a C-1 to C-5 alkyloxy and said oligo flexible tethered groups, and at least one of R₃, R₄, R₅, R₆, and R₇, is selected from said oligo flexible tethered groups, unless the moiety E-A-L in structure (5) contains at least one said oligo flexible tethered group, L is either a direct valence bond or a linking moiety derived from a 1,1-diarylethene, A segment is said polar block copolymer segment comprised either alkyl 2-methylenealkanoate derived repeating units, lactone derived repeat units, oxirane derived repeat units, oxetane derived repeating units, or cyclic carbonate derived repeat units; E is said end groups selected from H, an alkyl, a carbonylalkyl (—C═O-alkyl), a carbonyloxyalkyl (—C═O—O-alkyl), and an alkyl 2-arylacrylate derived end group (—CH₂—CH(Aryl)(C(═O))—O-alkyl) and n4 is the number of repeat units. In one aspect of this embodiment, L is a direct valence bond. In another aspect of this embodiment, L is a linking moiety derived from a 1, 1-diarylethene. In yet another aspect of this embodiment, L is a linking moiety derived from a 1,1-diphenylethene derivative. In still another aspect of this embodiment R₅, and R₆, are selected from H, a C-1 to C-5 alkyl, a halide, a C-1 to C-5 alkyloxy. In yet another aspect of this embodiment, R₅, R₆, are selected from said oligo flexible tethered groups. In still another aspect of this embodiment, R₃, R₄, and R₇, are selected from said oligo flexible tethered group. In still another aspect of this embodiment, R₃, R₄, R₅, R₆, and R₇, is from H, a C-1 to C-5 alkyl, a halide, and a C-1 to C-5 alkyloxy. In yet another aspect of this embodiment, said oligo flexible tethered group if present on an aromatic ring is at a para or meta position, in another aspect of this embodiment it is present at a meta position in yet another embodiment it is present at a para position.

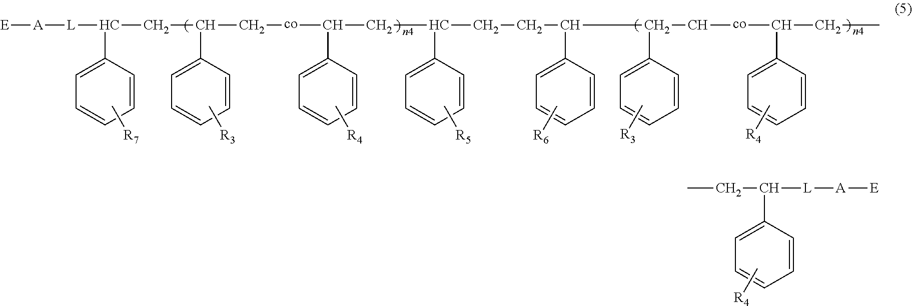

In another aspect of the block copolymer of structure (5), described herein, E-A-L has structure (3a), wherein * represents the attachment point of the E-A-L moiety to B, R₁, and R₂, are individually selected from H, a C-1 to C-5 alkyl, a halide, a C-1 to C-5 alkyloxy and said oligo flexible tethered groups, R₈, and R₉, are individually selected from a C-1 to C-5 alkyl, and said oligo flexible tethered groups, R₁₀ is H or a C-1 to C-5 alkyl, R₁₁ is H, C-1 to C-5 alkyl, a halide or a C-1 to C-5 alkyloxy; wherein further at least one of R₁, R₂, R₈, and R₉, is selected from said oligo flexible tethered groups, unless said B has at least one said oligo flexible tethered group, and n5 is the number of repeat units.

In another aspect of the block copolymer of structure (5), where E-A-L has structure (3a), described herein, R₈ is selected from said oligo flexible tethered groups, R₁ and R₂ are individually selected from H, a C-1 to C-5 alkyl, a halide, and a C-1 to C-5 alkyloxy. In another aspect of this embodiment, said oligo flexible tethered group is an oligo linear alkylene tethered group. In yet another aspect of this embodiment, said oligo flexible tethered group is an oligo ether tethered group. In still another aspect of this embodiment, said oligo flexible tethered group is an oligo dialkyl siloxane tethered group. In yet another aspect of this embodiment, said oligo flexible tethered group if present on an aromatic ring is at a para or meta position, in another aspect of this embodiment it is present at a meta position in yet another embodiment it is present at a para position.

In another aspect of the block copolymer of structure (5), where E-A-L has structure (3a), described herein, R₉ and R₈ are individually selected from said oligo flexible tethered groups, R₁ and R₂ are individually selected from H, a C-1 to C-5 alkyl, a halide, and a C-1 to C-5 alkyloxy. In another aspect of this embodiment, said oligo flexible tethered group is an oligo linear alkylene tethered group. In yet another aspect of this embodiment, said oligo flexible tethered group is an oligo ether tethered group. In still another aspect of this embodiment, said oligo flexible tethered group is an oligo dialkyl siloxane tethered group. In yet another aspect of this embodiment, R₁, R₂ and R₈ are individually selected from said oligo flexible tethered groups. In still another aspect of this embodiment, said oligo flexible tethered groups is an oligo linear alkylene tethered group. In yet another aspect of this embodiment, said oligo flexible tethered group is an oligo ether tethered group. In still another aspect of this embodiment, said oligo flexible tethered group is an oligo dialkyl siloxane tethered group. In yet another aspect of this embodiment, said oligo flexible tethered group if present on an aromatic ring is at a para or meta position, in another aspect of this embodiment it is present at a meta position in yet another embodiment it is present at a para position.

In another aspect of the block copolymer of structure (5), where E-A-L has structure (3a), described herein, R₃, R₄, R₅, R₆, and R₇, are individually selected from H, a C-1 to C-5 alkyl, a halide, and a C-1 to C-5 alkyloxy. In yet another aspect of this embodiment, said R₃, R₄, R₅, R₆, and R₇, is at a para or meta position, in another aspect of this embodiment it is present at a meta position in yet another embodiment it is present at a para position.

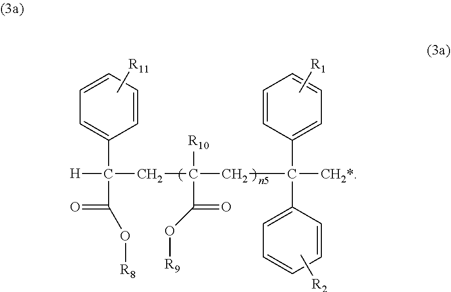

In another aspect of the block copolymer of structure (5), described herein, E-A-L has structure (4a), wherein * represents the attachment point of the E-A-L moiety to B, R₁, and R₂, are individually selected from H, a C-1 to C-5 alkyl, a halide, a C-1 to C-5 alkyloxy and said oligo flexible tethered groups, R₉ₐ and R_{5b} are individually selected from a C-1 to C-5 alkyl, and said oligo flexible tethered groups, R₁₀ₐ and R_{10b} are individually selected from H or a C-1 to C-5 alkyl, R₁₂ is H or a C-1 to C-5 alkyl. Further in this embodiment, at least one of R₁, R₂, R₉ₐ and R_{9b} is selected from said oligo flexible tethered groups, unless said B has at least one said oligo flexible tethered group, wherein n6 and n7 are the number of repeat units. In one aspect of this embodiment, R_{9b} is selected from said oligo flexible tethered group, R₉ₐ is a C-1 to C-5 alkyl, R₁, and R₂, are individually selected from H, a C-1 to C-5 alkyl, a halide, and a C-1 to C-5 alkyloxy. In another aspect of this embodiment, said oligo flexible tethered group is an oligo linear alkylene tethered group. In yet another aspect of this embodiment, said oligo flexible tethered group is an oligo ether tethered group. In still another aspect of this embodiment, said oligo flexible tethered group is an oligo dialkyl siloxane tethered group. In yet another aspect of this embodiment, said oligo flexible tethered group if present on an aromatic ring is at a para or meta position, in another aspect of this embodiment it is present at a meta position in yet another embodiment it is present at a para position. In yet another aspect of this embodiment, said oligo flexible tethered group if present on an aromatic ring is at a para or meta position, in another aspect of this embodiment it is present at a meta position in yet another embodiment it is present at a para position.

In another aspect of the block copolymer of structure (5), where E-A-L has structure (4a), R₉ₐ and R_{9b} are individually selected from a C-1 to C-5 alkyl, R₁, and R₂, are individually selected from H, a C-1 to C-5 alkyl, a halide, and a C-1 to C-5 alkyloxy and said oligo flexible tethered group is an oligo ether tethered group, wherein further as at least one of R₁, and R₂ is selected from said oligo flexible tethered group. In another aspect of this embodiment, said oligo flexible tethered group is an oligo linear alkylene tethered group. In still another aspect of this embodiment, said oligo flexible tethered group is an oligo ether tethered group. In yet another aspect of this embodiment, said oligo flexible tethered group is an oligo dialkyl siloxane tethered group. In yet another aspect of this embodiment, said oligo flexible tethered group if present on an aromatic ring is at a para or meta position, in another aspect of this embodiment it is present at a meta position in yet another embodiment it is present at a para position.

In another aspect of the block copolymer of structure (5), where E-A-L has structure (4a), R₉ₐ and R_{9b} are individually selected from said oligo flexible tethered group, R₁, and R₂, are individually selected from H, a C-1 to C-5 alkyl, a halide, a C-1 to C-5 alkyloxy. In yet another aspect of this embodiment, said oligo flexible tethered group is an oligo linear alkylene tethered group. In still another aspect of this embodiment, said oligo flexible tethered group is an oligo ether tethered group. In yet another aspect of this embodiment, said oligo flexible tethered group is an oligo dialkyl siloxane tethered group. In yet another aspect of this embodiment, said oligo flexible tethered group if present on an aromatic ring is at a para or meta position, in another aspect of this embodiment it is present at a meta position in yet another embodiment it is present at a para position.

In another aspect of the block copolymer of structure (5), where E-A-L has structure (4a), described herein, R₃, R₄, R₅, R₆, and R₇, are individually selected from H, a C-1 to C-5 alkyl, a halide, and a C-1 to C-5 alkyloxy. In another aspect of the block copolymer of structure (5), where E-A-L has structure (4a), described herein, R₃, R₄, R₅, R₆, and R₇, are individually selected from H, a C-1 to C-5 alkyl, a halide, and a C-1 to C-5 alkyloxy. In yet another aspect of this embodiment, R₃, R₄, R₅, R₆, and R₇, are individually at a para or meta position, in another aspect of this embodiment they are present at a meta position in yet another embodiment they are present at a para position.

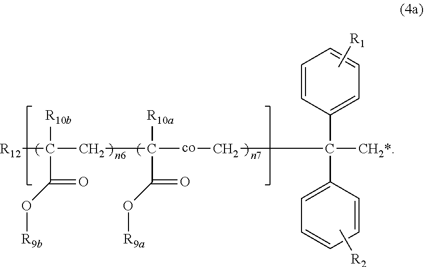

Another aspect of this invention is a block copolymer of structure (6), wherein A₁ is a polar block copolymer segment which has a T_{g} from about 50° C. to about 100° C., comprised of either alkyl 2-methylenealkanoate derived repeating units, lactone derived repeat units, oxirane derived repeat units, oxetane derived repeating units, or cyclic carbonate derived repeat units; and B₁ is a styrenic block copolymer segment, which has a T_{g} from about 50° C. and to about 100° C. Also, in this embodiment B₂ is block copolymer segment with a T_{g} ranging from about −5° C. to about −50° C., which comprises repeat units derived from either an olefin selected from the group consisting of an alkene, an alkadiene, and an alkatriene, or a from mixture of at two different olefins selected from this group. Further in this embodiment L₁ is either a direct valence bond or a linking moiety derived from a 1,1-diarylethene and E₁ are end groups selected from H, an alkyl, a carbonylalkyl (—C═O-alkyl), a carbonyloxyalkyl (—C═O—O-alkyl, and an alkyl 2-arylacrylate derived end group (—CH₂—CH(Aryl)(C(═O))—O-alkyl). Further, said block copolymer of structure (6) has a polydispersity ranging from 1 to about 1.09.

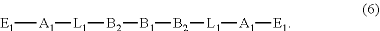

In another aspect of the block copolymer of structure (6), the repeat units in B₂ are derived from an alkene. In yet another aspect said B₂ is derived from an alkadiene. In still another aspect B₂ is derived from an alkadiene is a conjugated diene.

In another aspect of the block copolymer of structure (6), said B₂ is comprised of a mixture of at least two different olefinic repeat units having structures (7a), (7b), (7c), and (7d), derived from an alkadiene, wherein R_{d}, R_{d1}, R_{d2}, R_{d3}, Rₑ, Rₑ₁, Rₑ₂, and Rₑ₃, are individually selected from the group consisting of a H, and a C-1 to C-8 alkyl, and further wherein the total mole % of these olefinic repeat units in said block copolymer ranges from about 3 mole % to about 50 mole %. In another aspect of this embodiment n R_{d}, R_{d1}, R_{d2}, and R_{d3} are the same and are selected from a H, or a C-1 to C-8 alkyl, and. Rₑ, Rₑ₁, Rₑ₂, and Rₑ₃, are selected from a H, or a C-1 to C-8 alkyl.

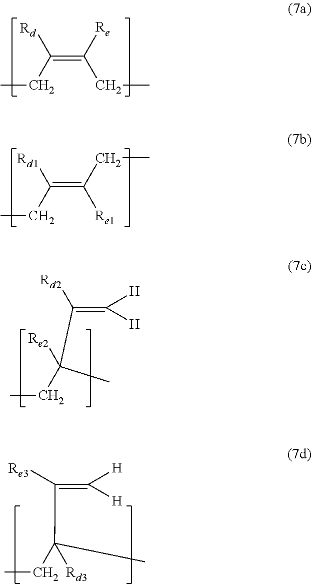

In another aspect of the block copolymer of structure (6), said B₂ is comprised of repeat units derived from either ethylene, propylene, butylene, pentylene, hexylene, heptylene, octylene, isoprene, 3-methylenepent-1-ene, 3-methylenehex-1-ene, 3,4-dimethylenehexane, 2-methyl-3-methylenepent-1-ene, 1,3-butadiene, ethylidene norbornene (2-ethylidene-5-norbornene), dicyclopentadiene, vinyl norbornene (2-vinylbicyclo[2.2.1]hept-2-ene), chloroprene(2-chlorobuta-1,3-diene), or a mixture of at least two of these.

In another aspect of the block copolymer of structure (6), described herein, where said B₂ is comprised of repeat units derived from an alkadiene, said alkadiene, is an unconjugated diene.

In another aspect of the block copolymer of structure (6), described herein where said B₂ is comprised of repeat units derived from an alkatriene.

In another aspect of the block copolymer of structure (6), described herein where said B₂ is comprised of repeat units derived from a mixture of at least 2 different olefins selected from the group consisting of an alkene, an alkadiene, and an alkatriene.

In another aspect of the block copolymer of structure (6), described herein, said B₂ further comprises styrenic repeat units.

In another aspect of the block copolymer of structure (6), described herein, said polar block copolymer segment A₁ is comprised of repeat units derived from a lactone. In one aspect of this embodiment said lactone is a mono-lactone such as caprolactone and the like. In another aspect of this embodiment said lactone is di-lactone such as lactide and the like.

In another aspect of the block copolymer of structure (6), described herein, said polar block copolymer segment A₁ is comprised of repeat units derived from an oxirane. In one aspect of this embodiment said repeat units are derived from oxetane. In another aspect of this embodiment said repeat units are derived from a substituted oxetane. In another aspect of this embodiment they are derived from an alkyl substituted oxetane.

In another aspect of the block copolymer of structure (6), described herein, said polar block copolymer segment A₁ is comprised of repeat units derived from an oxirane. In one aspect of this embodiment said repeat unit is derived from oxirane. In another aspect they are derived from a substituted oxirane. In yet another aspect of this embodiment they are derived from an alkyl substituted oxirane. In one aspect of this embodiment they are derived from 2-methyloxirane.

In another aspect of the block copolymer of structure (6), described herein, said polar block copolymer segment A₁ is comprised of repeat units derived from a cyclic carbonate. In one aspect of this embodiment they are derived from 1,3-dioxolan-2-one. In another aspect of this embodiment they are derived from a substituted 1,3-dioxolan-2-one. In yet another aspect of this embodiment it is derived from a 2-alkyl-dioxolan-2-one. In still another aspect of this embodiment they are derived from 2-methyl-dioxolan-2-one.

In another aspect of the block copolymer of structure (6), described herein, said polar block copolymer segment A₁ is comprised of alkyl 2-methylenealkanoate derived repeating units. In one aspect of this embodiment said alkyl 2-methylenealkanoate is selected from ones having any one the following structures:

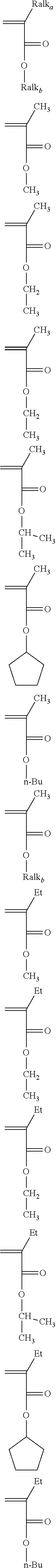

In another aspect of the block copolymer of structure (6), described herein, said polar block copolymer segment A₁ is comprised of methyl methacrylate derived repeating units.

In another aspect of the block copolymer of structure (6), described herein, said polar block copolymer segment A₁ is comprised of oxirane derived repeat units.

In another aspect of the block copolymer of structure (6), described herein, said polar block copolymer segment A₁ is comprised of carbonate derived repeat units.

In another aspect of the block copolymer of structure (6), described herein, said polar block copolymer segment A₁ has a M_{w} between 20,000 and about 200,000, and said non-polar block copolymer segment has an M_{w} between 20,000 and about 200,000, In another aspect of the block copolymer of structure (6), described herein, said polar block copolymer segment Aᵢ segment has a M_{w} between about 20,000 and about 200,000, and said non-polar styrenic block copolymer segment B has a M_{w} between 20,000 and about 200,000. In another aspect of this embodiment said polar block copolymer segment Aᵢ segment has a M_{w} between about 30,000 and about 170,000, and said non-polar styrenic block copolymer segment B has a M_{w} between 40,000 and about 160,000. In another aspect of this embodiment said polar block copolymer segment A₁ segment has a M_{w} between about 30,000 and about 167,000, and said non-polar styrenic block copolymer segment B has a M_{w} between 40,000 and about 150,000.

In another aspect of the block copolymer of structure (1), described herein, said polar block copolymer segment Aᵢ segment has a Mₙ between about 20,000 and about 200,000, and said non-polar styrenic block copolymer segment B has a Mₙ between 20,000 and about 200,000. In another aspect of this embodiment said polar block copolymer segment A₁ segment has a Mₙ between about 25,000 and about 170,000, and said non-polar styrenic block copolymer segment B has a Mₙ between 30,000 and about 160,000. In another aspect of this embodiment said polar block copolymer segment A₁ segment has a Mₙ between about 28,000 and about 155,000, and said non-polar styrenic block copolymer segment B has a Mₙ between 40,000 and about 135,000.

In another aspect of the block copolymer of structure (6), described herein, L₁ is a direct valence bond.

In another aspect of the block copolymer of structure (6), described herein, L₁ is a linking group derived from a 1,1-diarylethene.

In another aspect of the block copolymer of structure (6), described herein, E₁ is either H or an alkyl.

In another aspect of the block copolymer of structure (6), described herein, E₁ is a group derived from an alkyl-2-arylacrylate.

In another aspect of the block copolymer of structure (6), described herein, E is a carbonylalkyl (—C═O-alkyl), or a carbonyloxyalkyl (—C═O—O-alkyl).

In another aspect of the block copolymer of structure (6), described herein, it more specifically has structure (7) which comprises a central non-polar styrenic block copolymer segment attached at either end to the moiety —B₂-A₁-E₁ wherein R₁ₐ, R₂ₐ, R₃ₐ, R₄ₐ, R₅ₐ, R₆ₐ, and R₇ₐ, are individually selected from H, a C-1 to C-5 alkyl, a halide, a C-1 to C-5 alkyloxy, n8 is the number of repeat units. In one aspect of this embodiment, R₁ₐ, R₂ₐ, R₃ₐ, R₄ₐ, R₅ₐ, R₆ₐ, and R₇ₐ, are H. In another aspect of this embodiment, B₂ is comprised of a mixture of at least two repeat units derived from an olefin. In another aspect of this embodiment B₂ is comprised of a mixture of least two different repeat units derived from an alkadiene. In another aspect of this embodiment B₂ is comprised of a mixture of two different olefinic repeat units derived from a conjugated diene. In another aspect of this embodiment B₂ is comprised of at least two different repeat units having structures (7a), (7b), (7c), and (7d); wherein R_{d}, R_{d1}, R_{d2}, R_{d3}, Rₑ, Rₑ₁, Rₑ₂, and Rₑ₃, are individually selected from the group consisting of a H, and a C-1 to C-8 alkyl, and further wherein the total mole % of these olefinic repeat units in said block copolymer ranges from about 3 mole % to about 50 mole %. In another aspect of this embodiment, R₁ₐ, R₂ₐ, R₃ₐ, R₄ₐ, R₅ₐ, R₆ₐ, and R₇ₐ, are H. In still another aspect of this embodiment, R_{d}, R_{d1}, R_{d2}, R_{d3}, Rₑ, Rₑ₁, Rₑ₂, and Rₑ₃, are individually selected from the group consisting of a H, and a C-1 to C-8 alkyl, and the total mole % of these olefinic repeat units in said block copolymer ranges from about 3 mole % to about 50 mole %. In yet another aspect of this embodiment R_{d}, R_{d1}, R_{d2}, and R_{d3} are the same and are selected from a H, or a C-1 to C-8 alkyl, and, Rₑ, Rₑ₁, Rₑ₂, and Rₑ₃, are selected from a H, or a C-1 to C-8 alkyl. In another aspect of this embodiment R_{d}, R_{d1}, R_{d2}, R_{d3}, Rₑ, Rₑ₁, Rₑ₂, and Rₑ₃ are individually present at either a para or meta position, in another embodiment they are present at a para position, in yet another embodiment they are present at a meta position.

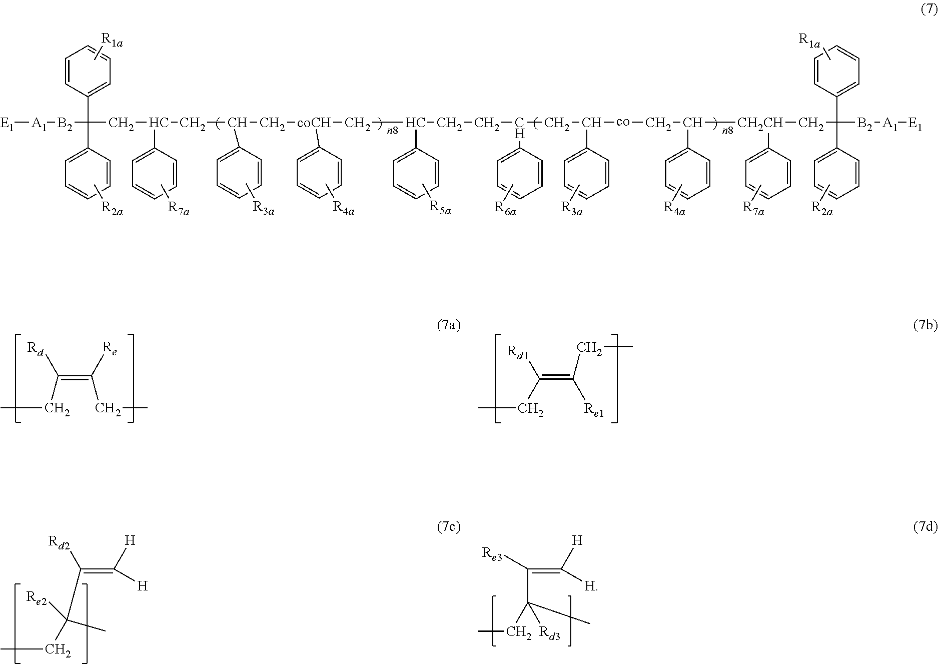

In another aspect of the block copolymer of structure (6), having the more specific structure (7), as described herein, said B₂ is a block copolymer segment whose repeat units are derived from isoprene or butadiene. In one aspect of this embodiment it is derived from isoprene. In another aspect of this embodiment it is derived from butadiene.

In another aspect of the block copolymer of structure (7), described herein, said polar block copolymer segment Aᵢ segment has a M_{w} between about 20,000 and about 200,000, and said non-polar styrenic block copolymer segment B₁ has a M_{w} between 20,000 and about 200,000. In another aspect of this embodiment said polar block copolymer segment Aᵢ segment has a M_{w} between about 25,000 and about 150,000 and said non-polar styrenic block copolymer segment B₁ has a M_{w} between 40,000 and about 140,000. In another aspect of this embodiment said polar block copolymer segment Aᵢ segment has a M_{w} between about 29,000 and about 120,000 and said non-polar styrenic block copolymer segment B₁ has a M_{w} between 45,000 and about 110,000.

another aspect of the block copolymer of structure (7), described herein, said polar block copolymer segment Aᵢ segment has a Mₙ between about 20,000 and about 200,000, and block copolymer segment B₂ has a Mₙ between 20,000 and about 200,000. In another aspect of this embodiment said polar block copolymer segment Aᵢ segment has a Mₙ between about 27,000 and about 145,000, and block copolymer segment B₂ has a Mₙ between 43,000 and about 135,000. In another aspect of this embodiment said polar block copolymer segment Aᵢ segment has a Mₙ between about 28,000 and about 115,000, and copolymer segment B₂ has a Mₙ between 40,000 and about 100,000.

In another aspect of the block copolymer of structure (6), having the more specific structure (7), as described herein, said polar block copolymer segment A₁ is comprised of repeat units derived from a lactone.

In another aspect of the block copolymer of structure (6), having the more specific structure (7), as described herein, said polar block copolymer segment A₁ is comprised of alkyl 2-methylenealkanoate derived repeating units.

In another aspect of the block copolymer of structure (6), having the more specific structure (7), as described herein, E₁ is H.

Another aspect of this invention is a formulation which comprises any one the different embodiments of the inventive block copolymers described herein and a spin casting solvent. This includes the block copolymer families embodied in the different embodiments of the two different block copolymers families of structure (1) and structure (6), and also the different embodiments of these two block copolymers families as described herein. by these including block copolymer of structure (1).

In another aspect of this inventive composition, it comprises at least two different block copolymers which belong to the block copolymer family embodied by structure (1) and the different embodiments of this block copolymer described herein.

In another aspect of this inventive composition, it comprises at least two different block copolymers which belong to the block copolymer family embodied by structure (6) and the different embodiments of this block copolymer as described herein.

In another aspect of this inventive composition, it comprises at least two different block copolymers at least one of which belong to the block copolymer family embodied by structure (1) at least one of which belongs to the block copolymer family embodied by structure (6) and their different embodiments as described herein.

In another aspect of this inventive composition, it comprises at least one block copolymer which belong to the block copolymer family embodied by structure (1) in any one its different embodiments, as described herein, and further comprises another type of block copolymer. In one aspect of this embodiment this block copolymer would be a diblock or triblock copolymer of a styrenic repeat units and alkyl 2-methylenealkanoate derived repeating units. In one aspect of this embodiment said block copolymer would be a diblock copolymer of styrene and methyl methacrylate.

In another aspect of this inventive composition, it comprises at least one block copolymer which belong to the block copolymer family embodied by structure (6) in any one its different embodiments, as described herein, and further comprises another type of block copolymer. In one aspect of this embodiment this block copolymer would be a diblock or triblock copolymer of a styrenic repeat units and alkyl 2-methylenealkanoate derived repeating units. In one aspect of this embodiment said block copolymer would be a diblock copolymer of styrene and methyl methacrylate.

In another aspect of this inventive composition, it comprises at least one block copolymer which belong to the block copolymer family embodied by structure (1) in any one its different embodiments, as described herein, and further comprises a homopolymer. In one aspect of this embodiment said homopolymer is a homopolymer of an alkyl 2-methylenealkanoate. In one aspect of this embodiment said homopolymer is a homopolymer of methyl methacrylate.

In another aspect of this inventive composition, it comprises at least one block copolymer which belong to the block copolymer family embodied by structure (6) in any one its different embodiments as described herein and further comprises a homopolymer. In one aspect of this embodiment said homopolymer is a homopolymer of an alkyl 2-methylenealkanoate. In one aspect of this embodiment said homopolymer is a homopolymer of methyl methacrylate.

In inventive composition described herein, the spin casting solvent, in one embodiment, is selected from an organic spin casting which is a suitable solvent for dissolving the above described inventive compositions include. a glycol ether derivative such as ethyl cellosolve, methyl cellosolve, propylene glycol monomethyl ether (PGME), diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate (PGMEA); carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate (EL), ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; a ketal or acetal like 1,3 dioxalane and diethoxypropane; lactones such as butyrolactone; an amide derivative such as dimethylacetamide or dimethylformamide, anisole, and mixtures thereof.

Additionally, the above described inventive composition may further comprise additives selected from the group consisting of: surfactants, inorganic-containing polymers; additives including small molecules, inorganic-containing molecules, surfactants, photoacid generators, thermal acid generators, quenchers, hardeners, cross-linkers, chain extenders, and the like; and combinations comprising at least one of the foregoing, wherein one or more of the additional components and/or additives co-assemble with the block copolymer to form the block copolymer assembly.

Another aspect of this invention is a method of vertically orienting first and second block copolymer domains over an unpatterned substrate using a layer of a block copolymer having a periodicity of L₀ comprising the steps of:
a) forming a coating layer of a block copolymer using an inventive composition, as described herein, on said unpatterned substrate; and,
b) annealing the layer of the block copolymer to generate a non-zero positive integer number of first and second block copolymer domains, vertically oriented on said unpatterned substrate.

Another aspect of this invention is a method of vertically orienting first and second block copolymer domains over a first patterned substrate where the height of topography of the pattern on the substrate is at least 0.7 times L₀ and aligning the domains with the pattern, using a coating comprised of a block copolymer having a periodicity of L₀ comprising the steps of:
a1) forming a coating layer of the composition using an inventive composition, as described herein, on said first topographical substrate, wherein the thickness of the average thickness of the coating layer of the block copolymer is less than the height of the topography of the first topographical substrate, wherein the block copolymer layer is laterally confined by the topography; and,
b1) annealing the block copolymer layer to generate first and second block copolymer domains, vertically oriented on said first patterned substrate, and confined within the recessed region.

Another aspect of this invention is a method of vertically orienting, first and second block copolymer domains with a periodicity of L₀ over a second patterned substrate having a topographical pattern with the height of topography larger than 0.7 times L₀ and a pitch P1 where the pitch P1 is a non-zero positive integer multiplied by L₀, and aligning the domains with the pattern comprising the steps of:
a2) forming a coating layer of a block copolymer using an inventive composition, as described herein, on said second patterned substrate, where the thickness of the coating layer of the block copolymer is more than the height of the topography of the second patterned substrate; and,
b2) annealing the block copolymer layer to generate a non-zero positive integer number of first and second block copolymer domains vertically oriented on said second patterned substrate and aligning them to the second patterned substrate where the sum of vertically oriented domains is equal or larger than the pitch P1 the of topographical pattern.

Another aspect of this invention is a method of vertically orienting first and second block copolymer domains over a substrate having a surface chemical prepattern having a pitch P2, where the pitch P2 is a non-zero positive integer multiplied by L₀ and aligning the domains comprising the steps of:
a) forming a coating layer of a block copolymer using an inventive composition, as described herein, on the substrate having a surface chemical prepattern; and,
b) annealing the block copolymer layer to generate vertically oriented first and second block copolymer domains aligned with the substrate having a surface chemical prepattern having a pitch P2.

Another aspect of this invention is a compound of structure (C1), wherein R_{1b}, R_{1c}, R_{2b} and R_{2c} are individually selected from H, a halide, a C-1 to C-4 alkyl, a C-1 to C-4 alkyloxy and an oligo flexible tethered groups, wherein at least one of R_{1b}, R_{2b}, R_{1c}, and R_{2c}, is an oligo flexible tethered group and R_{3b}, R_{3c}, R_{4b}, R_{4c}, R_{5b} and R_{5c} are individually selected from H, a halide, a C-1 to C-4 alkyl, and a C-1 to C-4 alkyloxy;

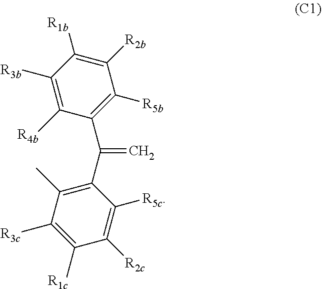

In one embodiment of the compound of structure (C1), R_{1b}, R_{1c}, R_{2b} and R₂, are individually selected from H, and an oligo flexible tethered group.

In another embodiment of the compound of structure (C1), only one of R_{1b} or R₂ₑ and only one of R_{1c} and R₂, is an oligo flexible tethered group.

In another embodiment of the compound of structure (C1), described above, only one of R_{1b} or R_{2b} or only one of R_{1c} and R₂, is an oligo flexible tethered group.

In another embodiment of the compound of structure (C1), described above, only R_{1b} is an oligo flexible tethered group.

In another embodiment the compound of structure (C1), described above, only R_{2b} is an oligo flexible tethered group.

In another embodiment the compound of structure (C1), described above, only R_{1b} and R_{1c} are oligo flexible tethered group.

In another embodiment the compound of structure (C1), described above, only R_{2b} and R₂, are oligo flexible tethered group.

In another embodiment the compound of structure (C1), described above, R_{3b}, R_{3c}, R_{4b}, R₄, R_{5b} and R₅, are H.

In another embodiment the compound of structure (C1), described above, said oligo flexible tethered group is a linear alkylene tethered group.

In another embodiment the compound of structure (C1), described above, said flexible oligo flexible tethered group is an oligo ether tethered group.

In another embodiment the compound of structure (C1), described above, said flexible oligo flexible tethered groups is an oligo dialkyl siloxane tethered group.

In another embodiment the compound of structure (C1), described above, it has structure (C1-A), wherein a is 7 to 19.

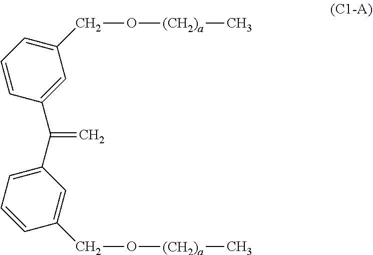

In another embodiment the compound of structure (C1), described above, it has structure (C1-B), wherein a is 7 to 19.

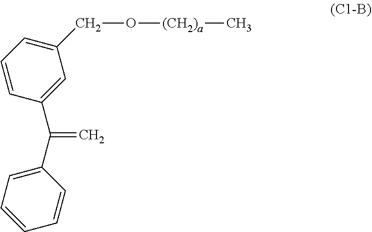

In another embodiment the compound of structure (C1), described above, it has structure (C1-C), wherein a is 7 to 19.

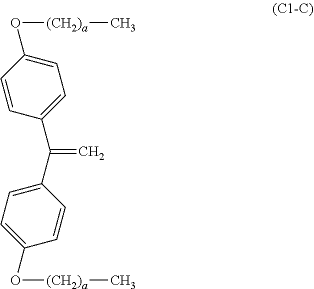

In another embodiment the compound of structure (C1), described above, it has structure (C1-D), wherein a is 7 to 19.

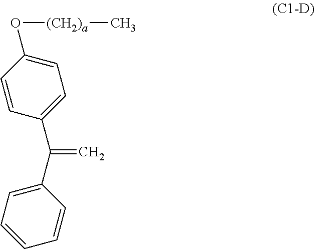

In another embodiment the compound of structure (C1), described above, it has structure (C1-E), wherein e2 is 2 to 8, and e3 is 1 to 8.

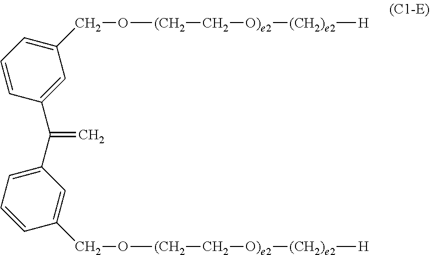

In another embodiment the compound of structure (C1), described above, it has structure (C1-F), wherein e2 is 2 to 8 and e3 is 1 to 8;

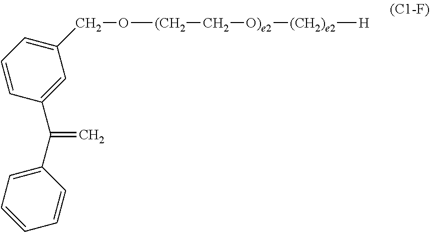

In another embodiment the compound of structure (C1), described above, it has structure (C1-G), wherein e2 is 2 to 8, and e3 is 1 to 8.

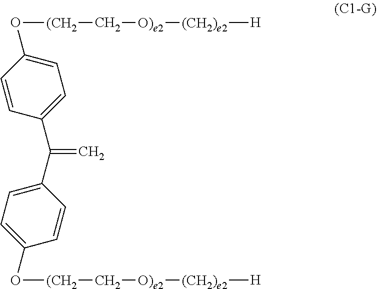

In another embodiment the compound of structure (C1), described above, it has structure (C1-H), wherein e2 is 2 to 8, and e3 is 1 to 8.

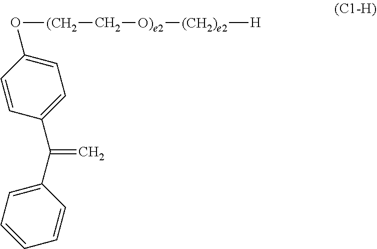

In another embodiment the compound of structure (C1), described above, it has structure (C1-I), wherein s is 6 to 18, and the alkyl moiety is a C-1 to C-8 alkyl.

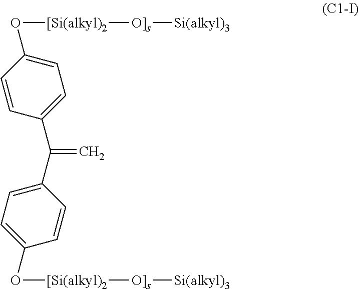

In another embodiment the compound of structure (C1), described above, it has structure (C1-J), wherein s is 6 to 18, and the alkyl moiety is a C-1 to C-8 alkyl.

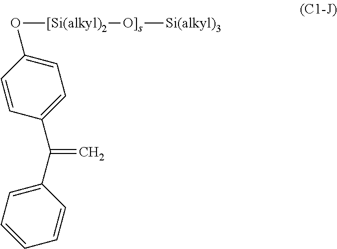

In another embodiment the compound of structure (C1), described above, it has structure (C1-K), wherein s is 6 to 18, and the alkyl moiety is a C-1 to C-8 alkyl.

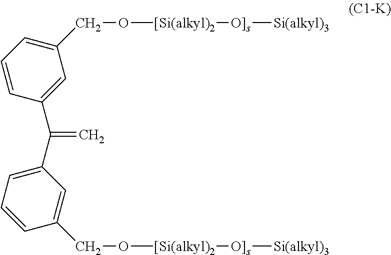

In another embodiment the compound of structure (C1), described above, it has structure (C1-L), wherein s is 6 to 18, and the alkyl moiety is a C-1 to C-8 alkyl.

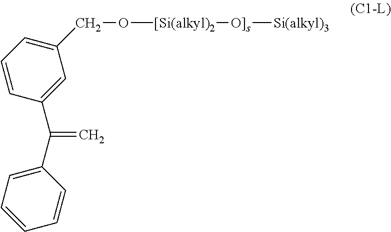

### EXAMPLES

### Chemicals

All chemicals unless otherwise indicated were purchased from Sigma Aldrich (3050 Spruce St., St. Louis, MO 63103). Chemicals used in anionic polymerization were purified as described in the literature (e.g. Techniques in High-Vacuum Anionic Polymerization” By David Uhrig and Jimmy Mays and Journal of Polymer Science: Part A: Polymer Chemistry, Vol. 43, 6179-6222 (2005))

Phenyl acrylate derivatives were synthesized by esterification of acryloyl chloride with corresponding hydroxyl compound under basic condition and DPE derivatives were synthesized by alkoxylation of DPE-(m)—CH₂Br (1-(bromomethyl)-3-(1-phenylvinyl)benzene) with corresponding hydroxyl compound under basic condition.

All synthetic experiments were carried out under N₂ atmosphere. Lithographic experiments were carried out as described in the text. The molecular weight of the copolymers was measured with a Gel Permeation Chromatograph. Gel permeation chromatography equipped with 100 Å, 500 Å, 10³ Å, 10⁵ Å and 10⁶ Å-ultrastyragel columns

Lithographic Experiments were done using a TEL Clean ACT8 track. SEM pictures were taken with an applied Materials NanoSEM_3D Scanning electron microscope picture are shown at either 1 FOV magnification or 2 FOV magnification (Field of view (FOV)=5 m).

Etching experiments were done using standard isotropic oxygen etching conditions for self-assembled films block copolymer of methyl methacrylate and styrene.

Unless otherwise indicated Molecular weight measurements (a.k.a. Mₙ polydispersity) were done by Gel permeation chromatography (PSS Inc. Germaby) equipped with 100 Å, 500 Å, 10 Å, 10⁵ Å and 10⁶ Å-ultrastyragel columns using THF solvent as an eluent. Polystyrene polymer standards were used for calibration.

DSC measurement of glass transition temperature were done using a TA instrument DSC Q1000 under nitrogen with a heating rate of 10° C./min. The glass transition temperature (T_{g}) was measured in first heating scan from 0 to 300° C. The midpoint of endothermic transition was considered

¹H NMR spectra were recorded using Bruker Advanced III 400 MHz spectrometer.

The molecular weight of the copolymers was measured with a Gel Permeation Chromatograph.

Chemicals, unless otherwise indicated, were obtained from the Sigma-Aldrich Corporation (St. Louis, Missouri).

### Comparative Example 1: The Synthesis of PMMA-b-PS-b-PMMA Block Copolymers

Styrene and methyl methacrylate and 1,1′-diphenylethylene (DPE) monomers were distilled in the presence of dehydrating agents into calibrated ampules and stored under N₂. Liquids were transferred into the reactor either via ampule or using stainless steel cannula under N₂. Into a dry 1 L round bottom reactor equipped with side arms for connecting ampules, magnetic stir bar, nitrogen/vacuum three-way septum adapter, was added 700 mL dry tetrahydrofuran. The temperature of the reactor was reduced to −78° C. using dry ice-acetone bath. Then, after titrating the impurities, 2.4 mL (0.154 M solution) of napthalene potassium as the initiator was added into the reactor. Then 15 g (0.144 moles) of styrene was added from ampule into the reactor under fast stirring. The reaction solution turned into yellow-orange and the reaction was stirred over 30 minutes. Subsequently, 0.12 g (0.0007 moles) of 1,1′-diphenylethylene (DPE) was added via ampule into the reactor. The orange color of the reaction mixture turned into dark brick-red indicating conversion of styrylpotassium active centers to styrene-DPE carbanion. A small amount (2 mL) of the reaction mixture was withdrawn for PS-DPE block molecular weight analysis. Then methyl methacrylate (15 g, 0.15 moles) was added via ampule. The reaction was terminated after 50 min with 1 mL of degassed methanol. The block copolymer was recovered by precipitation in excess isopropanol (5 times of the polymer solution) containing 10% water, filtered, and dried at 70° C. for 12 h under vacuum giving 28 g of PMMA-b-PS-b-PMMA) (94% yield). Gel permeation chromatography equipped with 100 Å, 500 Å, 10³ Å, 10⁵ Å and 10⁶ Å-ultrastyragel columns showed that the 1^{st} PS-DPE block had Mₙ (GPC)=87,000 g/mol and M_{w}/Mₙ=1.03 with respect to PS calibration standards. The triblock copolymer molecular weight obtained from GPC is M_{n,PMMA-b-PS-b-PMMA}=150,000 g/mol and M_{w}/Mₙ=1.07.

### Example 2: This System Demonstrates the Synthesis of Monotethered ABA with C13 Non-Polar Tethered Moieties (Scheme 1)

Styrene and methyl methacrylate monomers were distilled in the presence of dehydrating agents into calibrated ampules and stored under N₂. Liquids were transferred into the reactor either via ampule or using stainless steel cannula under N₂. Into a dry 1 L round bottom reactor equipped with side arms for connecting ampules, magnetic stir bar, nitrogen/vacuum three-way septum adapter, was added 700 mL dry tetrahydrofuran. The temperature of the reactor was reduced to −78° C. using dry ice-acetone bath. Then, after titrating the impurities, 3 mL (0.119 M solution) of naphthalene potassium as the initiator was added into the reactor. Then 15 g (0.144 moles) of styrene was added from ampule into the reactor under fast stirring. The reaction solution turned into yellow-orange and the reaction was stirred over 30 minutes. Subsequently, 0.17 g (0.00042 moles) of 1,1′-diphenylethylene-C₁₃H₂₅ (DPE-C₁₃H₂₅) (C13 non-polar tethered moieties) was added via ampule into the reactor. The orange color of the reaction mixture turned into dark brick-red indicating conversion of styrylpotassium active centers to styrene-DPE carbanion. A small amount (2 mL) of the reaction mixture was withdrawn for PS-DPE block molecular weight analysis. Then methyl methacrylate (15 g, 0.15 moles) was added via ampule. The reaction was continued for 50 minutes to complete polymerization of MMA. After 50 minutes 0.25 g (0.00075 moles) of phenyl acrylate C₁₃H₂₅ was added. The reaction mixture was then terminated with 1 mL of degassed methanol. The block copolymer was recovered by precipitation in excess isopropanol (5 times of the polymer solution) containing 10% water, filtered, and dried at 70° C. for 12 h under vacuum giving 28 g of PMMA-b-PS-b-PMMA) (94% yield). Gel permeation chromatography equipped with 100 Å, 500 Å, 10³ Å, 10⁵ Å and 10⁶ Å-ultrastyragel columns showed that the 1 PS-DPE block had Mₙ (GPC)=83,000 g/mol and M_{w}/Mₙ=1.04 with respect to PS calibration standards. The diblock copolymer molecular weight obtained from GPC is Mₙ,PMMA-b-PS-b-PMMA=168,000 g/mol and M_{w}/Mₙ=1.02.

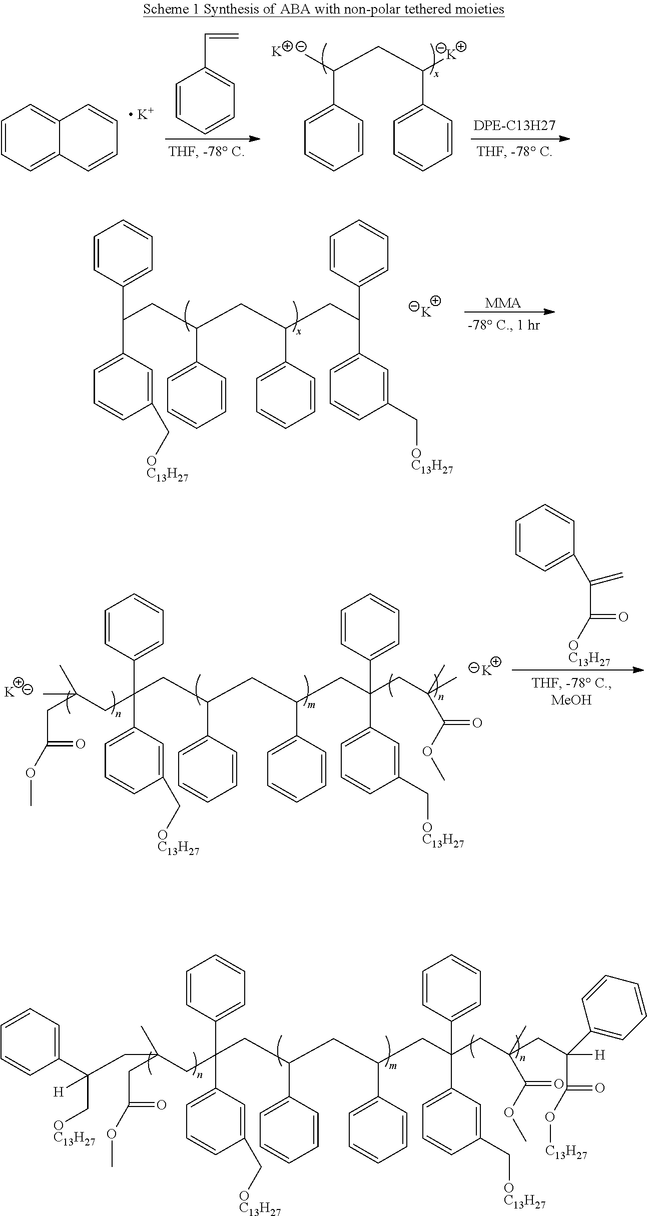

Example 3 and Example 4 were prepared in the same manner as Example 2, except that 1-((octadecyloxy)methyl)-3-(1-phenylvinyl)benzene (DPE-C18) and octadecyl 2-phenylacrylate (phenyl acrylate C18) (C18 non-polar tethered moieties were used for Example 3 and DPE-polar tether and phenyl acrylate polar tether were used for Example 4, whose structures are as follows:

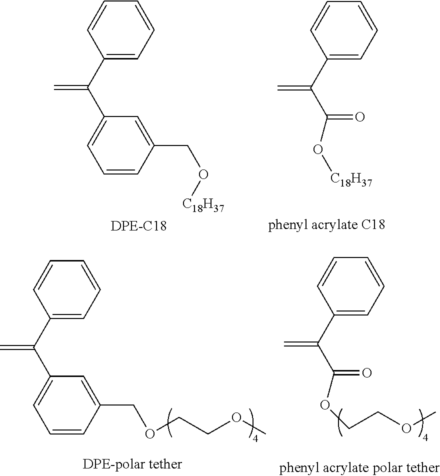

### Example 5: Synthesis of PMMA-b-PDEGMA-b-PS-b-PGEGMA-b-PMMA Block Copolymers

### (Scheme 2):

Styrene and methyl methacrylate and 1,1′-diphenylethylene (DPE) monomers were distilled in the presence of dehydrating agents into calibrated ampules and stored under N₂. Liquids were transferred into the reactor either via ampule or using stainless steel cannula under N₂. Into a dry 1 L round bottom reactor equipped with side arms for connecting ampules, magnetic stir bar, nitrogen/vacuum three-way septum adapter, was added 700 mL dry tetrahydrofuran. The temperature of the reactor was reduced to −78° C. using dry ice-acetone bath. Then, after titrating the impurities, 3.9 mL (0.176 M solution) of napthalene potassium as the initiator was added into the reactor. Then 24 g (0.230 moles) of styrene was added from ampule into the reactor under fast stirring. The reaction solution turned into yellow-orange and the reaction was stirred over 30 minutes. Subsequently, 0.12 g (0.00067 moles) of 1,1′-diphenylethylene was added via ampule into the reactor. The orange color of the reaction mixture turned into dark brick-red indicating conversion of styrylpotassium active centers to styrene-DPE carbanion. A small amount (2 mL) of the reaction mixture was withdrawn for PS-DPE block molecular weight analysis. Then diethylene glycol monomethyl ether (O3) methyl methacrylate (DEGMA) 4.8 g (0.0255 moles) was added via ampule. The reaction was continued for 10 minutes to complete polymerization of DEGMMA. After 10 minutes 19.2 g (0.192 moles) of methyl methacrylate was added. The reaction mixture was stirred for 50 minutes and then terminated with 1 mL of degassed methanol. The block copolymer was recovered by precipitation in excess isopropanol (5 times of the polymer solution) containing 10% water, filtered, and dried at 70° C. for 12 h under vacuum giving 45 g of PMMA-b-PDEGMA-b-PS-b-PGEGMA-b-PMMA (95% yield). Gel permeation chromatography equipped with 100 Å, 500 Å, 10³ Å, 10⁵ Å and 10⁶ Å-ultrastyragel columns showed that the 1^{st} PS-DPE block had M, (GPC)=83,700 g/mol and M_{w}/Mₙ=1.05 with respect to PS calibration standards. The diblock copolymer molecular weight obtained from GPC is M_{n,PMMA-b-PDEGMA-b-PS-b-PDEGMA-b-PMMA}=148,000 g/mol and M_{w}/Mₙ=1.09.

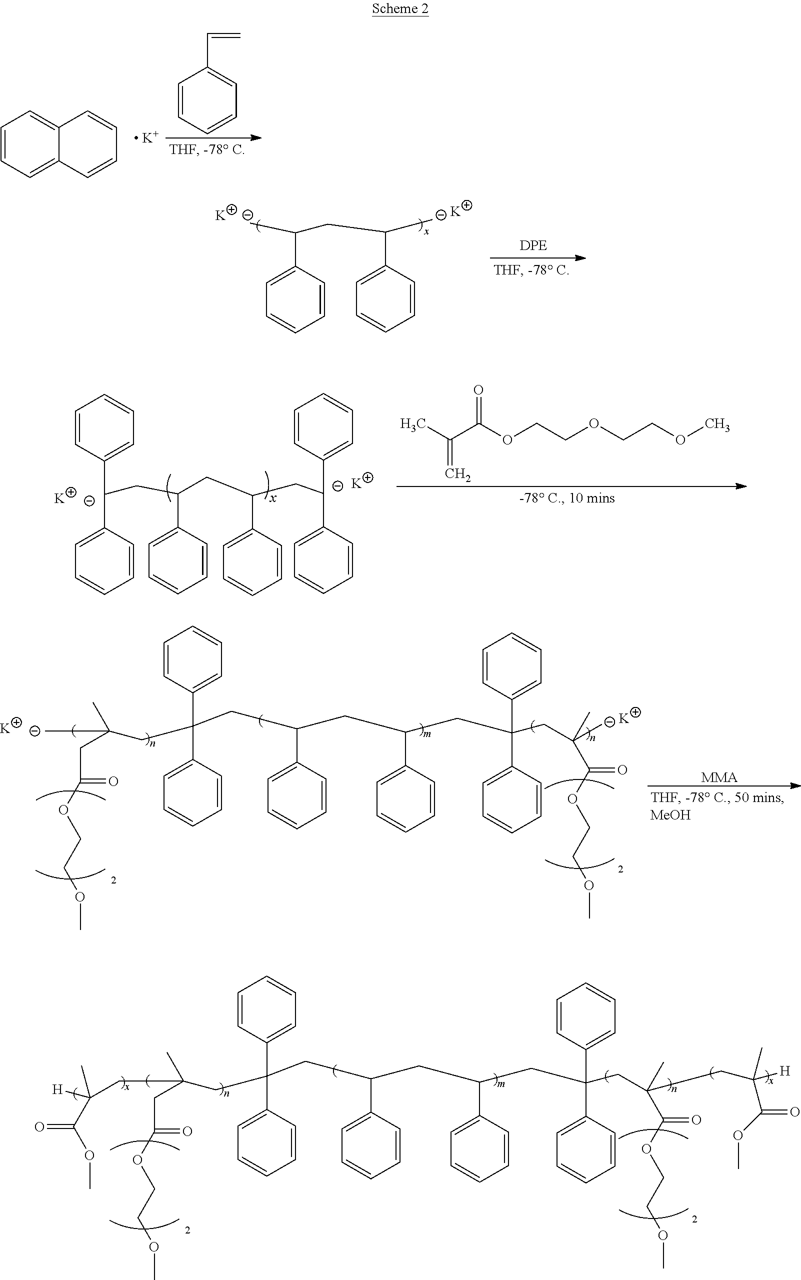

Example 6 and Example 10: were synthesized using similar procedure as described in example 5. The only difference was that in Example 6 synthesis is the used octyl styrene instead of using DEGMA and for Example 10 isoprene was used instead of DEGMA.

### Example 7: Synthesis of PMMA-b-PS-b-PC8S-b-PS-b-PMMA with Low T_{g} Octyl Styrene Multi-Tethered at the Center of PS Block

Styrene and methyl methacrylate monomers were distilled in the presence of dehydrating agents into calibrated ampules and stored under N₂. Liquids were transferred into the reactor either via ampule or using stainless steel cannula under N₂. Into a dry 1 L round bottom reactor equipped with side arms for connecting ampules, magnetic stir bar, nitrogen/vacuum three-way septum adapter, was added 700 mL dry tetrahydrofuran. The temperature of the reactor was reduced to −78° C. using dry ice-acetone bath. Then, after titrating the impurities, 2.4 mL (0.154 M solution) of napthalene potassium as the initiator was added into the reactor. Then 3.45 g (0.016 moles) of n-octyl styrene was added from the ampule into the reactor under fast stirring. The reaction mixture turned orange-red and the reaction was continued for 10 minutes. After that 15 g (0.144 moles) of styrene was added from ampule into the reactor. The reaction solution turned into yellow-orange and the reaction was stirred over 30 minutes. Subsequently, 0.12 g (0.00066 moles) of 1,1′-diphenylethylene was added via ampule into the reactor. The orange color of the reaction mixture turned into dark brick-red indicating conversion of styrylpotassium active centers to styrene-DPE carbanion. A small amount (2 mL) of the reaction mixture was withdrawn for PS-DPE block molecular weight analysis. Then methyl methacrylate (15 g, 0.15 moles) was added via ampule. The reaction was continued for 50 minutes to complete polymerization of MMA. The reaction mixture was then terminated with 1 mL of degassed methanol. The block copolymer was recovered by precipitation in excess isopropanol (5 times of the polymer solution) containing 10% water, filtered, and dried at 70° C. for 12 h under vacuum giving 28 g of PMMA-b-PS-b-PC8S-b-PS-b-PMMA (94% yield). Gel permeation chromatography equipped with 100 Å, 500 Å, 10 Å, 10⁵ Å and 10⁶ Å-ultrastyragel columns showed that the 1st PS-DPE block had Mₙ(GPC)=122,000 g/mol and M_{w}/Mₙ=1.03 with respect to PS calibration standards. The diblock copolymer molecular weight obtained from GPC is M_{n,PMMA-b-PS-b-Pos-b-PS-b-PMMA}=244,000 g/mol and M_{w}/Mₙ=1.04.

### Example 8: Synthesis of PMMA-b-P(S—Co—C8S)-b-PMMA with Low T_{g} Octyl Styrene Copolymerized (PC8S) in PS Block

Styrene, octyl styrene and methyl methacrylate monomers were distilled in the presence of dehydrating agents into calibrated ampules and stored under N₂. Liquids were transferred into the reactor either via ampule or using stainless steel cannula under N₂. Into a dry 1 L round bottom reactor equipped with side arms for connecting ampules, magnetic stir bar, nitrogen/vacuum three-way septum adapter, was added 700 mL dry tetrahydrofuran. The temperature of the reactor was reduced to −78° C. using dry ice-acetone bath. Then, after titrating the impurities, 2.7 mL (0.154 M solution) of napthalene potassium as the initiator was added into the reactor. Then a mixer of 3.45 g (0.016 moles) of n-octyl styrene and 15 g (0.144 moles) of styrene was added from the ampule into the reactor under fast stirring. The reaction mixture turned orange-red and the reaction was continued for 30 minutes. Subsequently, 0.12 g (0.00066 moles) of 1,1′-diphenylethylene was added via ampule into the reactor. The orange color of the reaction mixture turned into dark brick-red indicating conversion of styrylpotassium active centers to styrene-DPE carbanion. A small amount (2 mL) of the reaction mixture was withdrawn for PS-DPE block molecular weight analysis. Then the methyl methacrylate (15 g, 0.15 moles) was added via ampule. The reaction was continued for 50 minutes to complete polymerization of MMA. The reaction mixture was then terminated with 1 mL of degassed methanol. The block copolymer was recovered by precipitation in excess isopropanol (5 times of the polymer solution) containing 10% water, filtered, and dried at 70° C. for 12 h under vacuum giving 33 g of PMMA-b-P(S-co-C8S)-b-PMMA (94% yield). Gel permeation chromatography equipped with 100 Å, 500 Å, 10³ Å, 10⁵ Å and 10⁶ Å-ultrastyragel columns showed that the 1^{st} PS-DPE block had Mₙ (GPC)=78,000 g/mol and M_{w}/Mₙ=1.03 with respect to PS calibration standards. The diblock copolymer molecular weight obtained from GPC is M_{n,PMMA-b-P(S-co-C8S)-b-PS-b-PMMA}=138,000 g/mol and M_{w}/Mₙ=1.03.

### Example 9: This System Demonstrate the Synthesis of P(MMA-Co-C6MA)-b-P(S—Co—C8S)-b-P(MMA-Co-C6MA) with Low T_{g} Octyl Styrene Copolymerized in PS Block and Hexyl Methacrylate Copolymerized in PMMA Block

Styrene, octyl styrene, methyl methacrylate and hexyl methacrylate monomers were distilled in the presence of dehydrating agents into calibrated ampules and stored under N₂. Liquids were transferred into the reactor either via ampule or using stainless steel cannula under N₂. Into a dry 1 L round bottom reactor equipped with side arms for connecting ampules, magnetic stir bar, nitrogen/vacuum three-way septum adapter, was added 700 mL dry tetrahydrofuran. The temperature of the reactor was reduced to −78° C. using dry ice-acetone bath. Then, after titrating the impurities, 2.7 mL (0.154 M solution) of napthalene potassium as the initiator was added into the reactor. Then a mixer of 3.45 g (0.016 moles) of n-octyl styrene and 15 g (0.144 moles) of styrene was added from the ampule into the reactor under fast stirring. The reaction mixture turned orange-red and the reaction was continued for 30 minutes. Subsequently, 0.12 g (0.00066 moles) of 1,1′-diphenylethylene was added via ampule into the reactor. The orange color of the reaction mixture turned into dark brick-red indicating conversion of styrylpotassium active centers to styrene-DPE carbanion. A small amount (2 mL) of the reaction mixture was withdrawn for P(S-co-C8S)-DPE block molecular weight analysis. Then the mixture of methyl methacrylate (15 g, 0.15 moles) and hexyl methacrylate (2.89 g, 0.017 moles) was added via ampule. The reaction was continued for 50 minutes to complete polymerization of MMA and C6MA. The reaction mixture was then terminated with 1 mL of degassed methanol. The block copolymer was recovered by precipitation in excess isopropanol (5 times of the polymer solution) containing 10% water, filtered, and dried at 70° C. for 12 h under vacuum giving 40 g of P(MMA-co-C6MA)-b-P(S-co-C8S)-b-P(MMA-co-C6MA) (94% yield). Gel permeation chromatography equipped with 100 Å, 500 Å, 10³ Å, 10⁵ Å and 10⁶ Å-ultrastyragel columns showed that the 1 P(S-co-C8S)-DPE block had Mₙ (GPC)=87,000 g/mol and M_{w}/Mₙ=1.04 with respect to PS calibration standards. The diblock copolymer molecular weight obtained from GPC is M_{n, P(MMA-co-C6MA)-b-P(S-co-C8S)-b-PS-b-P(MMA-co-C6MA)}=154,000 g/mol and M_{w}/Mₙ=1.07. FIG. 7 shows the Kinetic enhancements of this ABA terpolymer with copolymerized low T_{g} octyl styrene in PS block and copolymerized hexyl methacrylate in PMMA block 0.1 FOV SEM images, Process conditions: V: 250° C./1 hour (N₂); EBR 2 min, spin dry, 110° C./1 min, FT=140 nm.

### Comparative Example 2: Synthesis of Random x-Linkable Copolymers (Underlayer Polymer 1)

Copolymer of Styrene, Methyl Methacrylate and 4-Vinylbenzycylobutene Synthesized with AIBN

A 2000-ml flask equipped with a condenser, temperature controller, heating mantle and mechanical stirrer were set up. 87.0 grams (0.84 moles) of styrene(S), 139.8 grams (1.40 moles) of methyl methacrylate (MMA), 72.4 grams (0.56 moles) of 4-Vinylbenzocyclobutene (VBCB) and 1.83 grams (0.011 moles) of Azobisisobutyronitrile (AIBN) initiator and 600 grams of anisole were added to the flask. The mechanical stirrer was turned on and set up at about 120 rpm. The reaction solution was then degassed by vigorously bubbling nitrogen through the solution for about 30 minutes at room temperature. After 30 minutes of degassing the heating mantle was turned on and the temperature controller was set at 70° C., and the stirred reaction mixture was maintained at this temperature for 20 hours. After this time the heating mantle was turned off and the reaction solution was allowed to cool down to about 40° C. Then the reaction mixture was poured into 12 L of isopropanol stirred with a mechanical stirring during the addition. During this addition, the polymer was precipitated out. The precipitated polymer was collected by filtration. The collected polymer was dried in vacuum oven at 40° C. About 170 grams of the polymer was obtained. This dried polymer was dissolved in 600 grams of THF and then filtered through a 0.2 um nylon filter. The filtered solution was then precipitated again into a stirred solution of 12 L methanol, the precipitated polymer collected and dried as before under vacuum at 40° C. In this manner, 150 grams (50% yields) of the polymer was obtained after dry. The polymer had an M_{w} of about 38 k and a polydispersity (PDI) of 1.5

### Processing Example 1: Self-Assembly of Block Copolymer (BCP) Comparative Example 1 Versus Example 2 (Table 1)

The polymers of Comparative Example 1 and Example 2 were individually dissolved in PGMEA to each, individually, form 3.2 wt % solution. These solutions where individually filtered using a 0.02 m PTFE filter. Filtered 0.33 wt % solutions of Underlayer Polymer 1 were then coated at 1500 rpm on SiOx wafers, and then baked at 250° C. for 2 min in air to produce SiOx wafers coated with the crosslinked neutral layer (FT 8 nm) of Underlayer Polymer 1. The wafers coated waters with this neutral layer were then individually coated with a 0.02 m PTFE filtered 3.2 wt % solution in PGMEA of a standard ABA triiblock copolymer of styrene and methyl methacrylate (PMMA-b-PS-b-PMMA) (Comparative Example 1) or a monotethered ABA with C13 non-polar tethered moieties (Example 2). These films were spin coated at 1,500 rpm and subsequently soft baked at 110° C. for 1 min were then annealed at 250° C. under N₂ for 1 hour. FIG. 5 shows a comparison of the self-assembled patterns of a film of Comparative Example 1 (FIG. 5A) and Example 2 (FIG. 5B), after plasma etching. These etching conditions were as follows: 02 (50 sccm): N₂ (50 sccm) for 30 sec, power=50 W, RIE=100, using a Trion etcher. Defects counts measured. Defects counts using Hitachi software. These Figures showed that the regular non-tethered ABA (FIG. 5A) showed a total defects of 101 while b) the monotethered ABA shows an improved defects of 60 with improved grain sizes and faster kinetics (FIG. 5B).

### Processing Example 2: Self-Assembly of Block Copolymer (BCP) Comparative Example 1 Versus Example 4 (Table 1)

The polymer of Example 4 was dissolved in PGMEA to form a 3.2 wt % solution. This solution was filtered using a 0.02 um PTFE filter and then at 1500 rpm on an Underlayer Polymer 1 coated SiOx wafers (as described in processing Example 1), and thus forms a coating of the polymer of Example 4. This coating of the polymer of Example 4 is heated at 250° C. for 1 hour. This material forms a self-assembled pattern in which an array of nanophase segregated lamellar perpendicular to the substrate form which contain the etchable block derived from methyl methacrylate. This microphase segregated array is one suitable to use for etching pattern transfer into the substrate of a line and space array. The ABA with polar tethered moieties of Examples 4 is expected to show a smaller number of network defects and better grain size than was observed with the regular non-tethered ABA terpolymer (FIG. 5A) (Comparative Example 1)

### Processing Example 3: Self-Assembly of Block Copolymer (BCP) Based on Example 8 (Table 1)

The polymer of Example 8 (multitethered C8S copolymerize with PS block) is dissolved in PGMEA to form 3.2 wt % solution. This solution was filtered using a 0.02 um PTFE filter and then coated at 1500 rpm on an Underlayer Polymer 1 coated SiOx wafers (as described in processing Example 1), and the wafer is subsequently baked at 250° C. for 1 hour. FIG. 6 shows that this material forms a self-assembled pattern in which an array of nanophase segregated lamellar perpendicular to the substrate are formed which contain the etchable block derived from methyl methacrylate. This microphase segregated array is one suitable to use for etching pattern transfer into the substrate of a line and space array. Moreover, films of this material show a smaller number of network defects as well much better grain size compared self-assembled films of Comparative Example 1, in view that Example 8 has faster kinetics and better assembling properties and grain size, than a standard ABA triblock copolymer processed under the same conditions. FIG. 6. shows a 1 FOV SEM image of the pattern obtained after etching and processing as follows: Annealing at 250° C./1 hour (N₂); EBR 2 min, spin dry, 110° C./1 min, FT=140 nm; and etching O₂ (50 sccm):N₂ (50 sccm) for 30 see, power=50 W, RIE=100, using Trion etcher. Defects counts measured. and 1 FOV SEM images A comparison of FIG. 6 with what is obtained with a standard ABA copolymer (FIG. 5A), under the same processing conditions, shows that this novel multitethered polymer apart from faster kinetic also showed improved grain sizes compared to the regular non-tethered ABA block copolymer.

### Processing Example 4: Self-Assembly of Block Copolymer (BCP) Based on Example 9 (Table 1)

The polymer of example 9 (multitethered copolymerize in both PS and PMMA block) was dissolved in PGMEA to form 3.2 wt % solution. This solutions was filtered using a 0.02 um PTFE filter and then coated at 1500 rpm on an Underlayer Polymer 1 coated SiOx wafer, (as described in processing Example 1), and the wafer was subsequently baked at 250° C. for 1 hour FIG. 7 shows that this material formed a self-assembled pattern in which an array of nanophase segregated lamellar perpendicular to the substrate were formed which contain the etchable block derived from methyl methacrylate. This microphase segregated array was one suitable to use for etching pattern transfer into the substrate of a line and space array. Moreover, films of this material showed a smaller number of network defects as well much better grain size compared self-assembled films of Comparative Example 1, indicating that the polymer of Example 9 had faster kinetics and better assembling properties than a standard ABA triblock copolymer. FIG. 7 shows the Kinetic enhancements observed in self-assembly of a film of Example 9 which is an ABA with copolymerized low T_{g} octyl styrene in PS block and copolymerized hexyl methacrylate in PMMA block 0.1 FOV SEM images, Process conditions: V: 250° C./1 hour (N₂); EBR 2 min, spin dry, 110° C./1 min, FT=140 nm. Specifically, FIG. 7. shows a 1 FOV SEM images of the pattern obtained after etching and processing as follows: Annealing at 250° C./1 hour (N₂); EBR 2 min, spin dry, 110° C./1 min, FT=140 nm; and etching 02 (50 sccm):N₂ (50 sccm) for 30 sec, power=50 W, RIE=100, using a Trion etcher. Defects counts measured. and 1 FOV SEM images A comparison of FIG. 7 with what is obtained with a standard ABA copolymer (FIG. 5A), under the same processing conditions, shows that this novel polymer apart from faster kinetic also showed improved grain sizes compared to the regular non-tethered ABA block copolymer.

### Processing Example 5: Self-Assembly of Block Copolymer (BCP) Based on Example 10 (Table 1)

The polymer of example 10 was dissolved in PGMEA to form 3.2 wt % solution. This solution was filtered using a 0.02 um PTFE filter and then coated at 1500 rpm on an Underlayer Polymer 1 coated SiOx wafer, (as described in processing Example 1), and the wafer was subsequently baked at 250° C. for 1 hour. FIG. 8 shows that polymer Example 10 formed a self-assembled pattern in which an array of nanophase segregated lamellar perpendicular to the substrate were formed which contain the etchable block derived from methyl methacrylate. This microphase segregated array was one suitable to use for etching pattern transfer into the substrate of a line and space array. Moreover, films of this material showed a smaller number of network defects as well much better grain size compared self-assembled films of Comparative Example 1. indicating that the polymer of Example 10 had faster kinetics and better assembling properties than a standard ABA triblock copolymer. FIG. 7: Shows the kinetic enhancements observed in self-assembly of a film of Example 10 which is an ABA with isoprene at the junction of PS-PMMA. Specifically, FIG. 8. shows a 1 FOV SEM images of the pattern obtained after processing as follows: Annealing at 250° C./1 hour (N₂); EBR 2 min, spin dry, 110° C./1 min, FT=140 nm. A comparison of FIG. 8 with what is obtained with a standard ABA copolymer, under the same processing conditions shows that this novel polymer apart from faster kinetic also showed improved grain sizes compared to the regular non-tethered ABA block copolymer.

TABLE 1
Triblock copolymers synthesis and charaterization data

| | Mₙ | | | | |
|---|---|---|---|---|---|
| | (non-polar | Mₙ * | PDI* | | |
| Sample ID | block)* | BCP's | (M_{w}/Mₙ) | Lo* | |
| Comparative ex 1 | 85K | 150K | 1.07 | 45.5 | nm |
| (non tethered ABA) | | | | | |
| Ex 2 (Monotethered C13 | 83K | 168K | 1.02 | 43 | nm |
| non-polar tethers) | | | | | |
| Ex 3 (Monotethered C18 | 111K | 219K | 1.03 | 51.4 | nm |
| non-polar tethers) | | | | | |
| Ex 4 (Monotethered O5 | 91K | 244K | 1.02 | 47.7 | nm |
| polar tethers) | | | | | |
| Ex 5 (Multitethered O3 at | 83.7K | 148K | 1.09 | 46.7 | nm |
| the junction of PS-PMMA) | | | | | |
| Ex 6 (Multitethered C8S at | 74K | 223K | 1.01 | 45.9 | nm |
| the junction of PS-PMMA) | | | | | |
| Ex 7 (Multitethered C8S at | 122K | 248K | 1.03 | 50 | nm |
| the center of PS block) | | | | | |
| Ex 8 (multitethered C8S | 79K | 138K | 1.03 | 43.7 | nm |
| copolymerize with PS | | | | | |
| block) | | | | | |
| Ex 9 (multitethered | 87K | 154K | 1.07 | 48.4 | nm |
| copolymerize in both | | | | | |
| PS and PMMA block) | | | | | |
| Ex 10 (Isoprene at the | 49K | 78K | 1.16 | 49 | nm |
| junction of PS-PMMA | | | | | |

Mn and PDI were measured by GPC. C8S (multitehtered with octystyrene unit; octyl tether group); O3, O5 number of oxygens in oligomeric diethylene glycol monomethyl ether tether group.

1. A block copolymer having structure (1), wherein
A segment is a polar block copolymer segment comprised of either alkyl 2-methylenealkanoate derived repeating units, lactone derived repeat units, oxirane derived repeat units, oxetane derived repeating units, or cyclic carbonate derived repeat units;
L is either a direct valence bond or a linking moiety derived from a 1,1-diarylethene;
B segment is a non-polar block copolymer segment comprised of styrenic repeat units,
E are end groups selected from H, an alkyl, a carbonylalkyl (—C═O-alkyl), a carbonyloxyalkyl (—C═O—O-alkyl, and an alkyl 2-arylacrylate derived end group (—CH₂—CH(Aryl)(C(═O))—O-alkyl); and further,
said block copolymer of structure (1) is multi-tethered with oligo flexible tethered groups which are selected from oligo linear alkylene tethered group, oligo ether tethered groups, and oligo dialkyl siloxane tethered groups, and these oligo flexible tethered groups are multi-tethered at positions selected from the following placements in the polymer block copolymer of structure (1):
said oligo flexible tethered groups are only present on segments A and are either randomly located along this segment on some of its repeat units or present on each of its repeat units,
said oligo flexible tethered groups are only present on segment B and are either randomly located along this segment on some of its repeat units or present on each of its repeat units,
said oligo flexible tethered groups are present on both segments A and segments B and are either randomly located along these segments on only some of its repeat units or present on each of their repeat units,
said oligo flexible tethered group are present on both E end groups, when these are an alkyl or an alkyl 2-arylacrylate derived end group (—CH₂—CH(Aryl)(C(═O))—O-alkyl),
said oligo flexible tethered groups are present on both L when L is a linking moiety derived from a 1,1-diarylethene,
said oligo flexible tethered groups are present in the center of the B segment; and
said oligo flexible tethered groups are present on at least one of A segments, B segments, L (when L is said linking moiety), and end groups E, and further wherein,
said block copolymer has a polydispersity ranging from 1 to about 1.09:

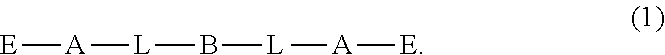

2. The block copolymer of claim 1 wherein said polar block copolymer segment A is comprised of repeat units derived from a lactone.

3. The block copolymer of claim 1 wherein said polar block copolymer segment A is comprised of repeat units derived from an alkyl 2-methylenealkanoate.

4. The block copolymer of claim 1, wherein said polar block copolymer segment A segment has a Mw between about 20,000 and about 200,000, and said non-polar styrenic block copolymer segment B has a Mw between 20,000 and about 200,000.

5-9. (canceled)

10. The block copolymer of claim 1, having structure (2) wherein R₁, R₂, R₃, R₄, R₅, R₆, and R₇, are individually selected from H, a C-1 to C-5 alkyl, a halide, a C-1 to C-5 alkyloxy and said oligo flexible tethered groups wherein further at least one R₁, R₂, R₃, R₄, R₅, R₆, and R₇, is selected from said oligo flexible tethered groups and n is the number of repeat units;

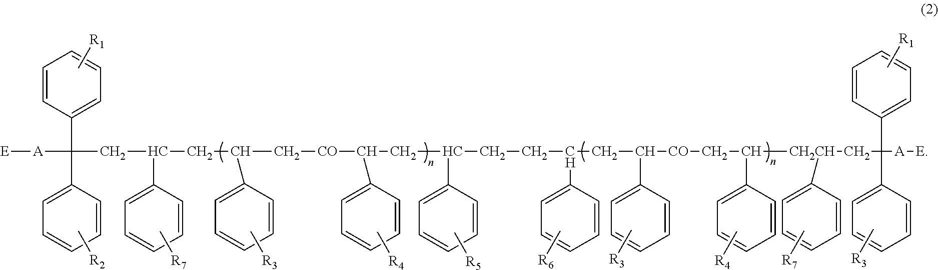

11. The block copolymer of claim 1 having structure (3), wherein
R₁, and R₂, are individually selected from H, a C-1 to C-5 alkyl, a halide, a C-1 to C-5 alkyloxy and said oligo flexible tethered groups,
R₈, and R₉, are individually selected from a C-1 to C-5 alkyl, and said oligo flexible tethered groups,
R₁₀ is H or a C-1 to C-5 alkyl,
R₁₁ is H, C-1 to C-5 alkyl, a halide or a C-1 to C-5 alkyloxy;
wherein further at least one R₁, R₂, R₈, and R₉, is selected from said oligo flexible tethered groups, and n1 is the number of repeat units;

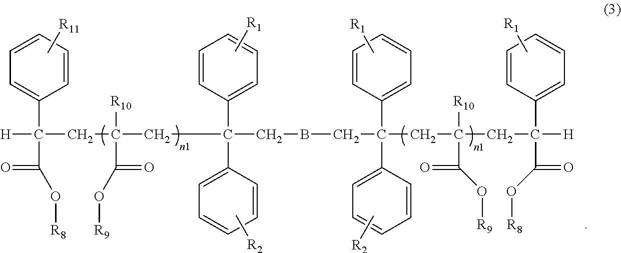

12-23. (canceled)

24. The block copolymer of claim 1 having structure (4), wherein
R₁, and R₂, are individually selected from H, a C-1 to C-5 alkyl, a halide, a C-1 to C-5 alkyloxy and said oligo flexible tethered groups,
R₉ₐ and R_{9b} are individually selected from a C-1 to C-5 alkyl, and said oligo flexible tethered groups,
R₁₀ₐ and R_{10b} are individually selected from H or a C-1 to C-5 alkyl,
R₁₂ is H or a C-1 to C-5 alkyl, wherein further,
at least one R₁, R₂, R₉ₐ and R_{9b} is selected from said oligo flexible tethered groups and n2 and n3 are the number of repeat units;

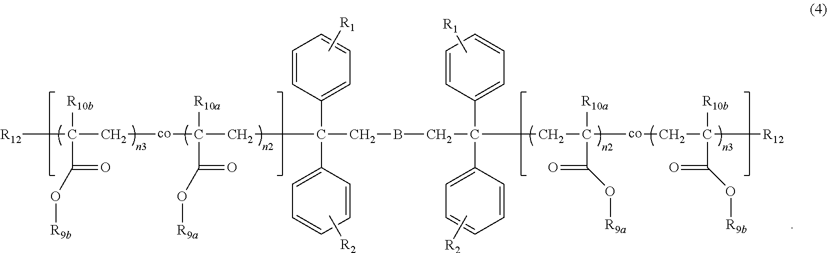

25-36. (canceled)

37. The block copolymer of claim 1 having structure (5), wherein
R₃, R₄, R₅, R₆, and R₇, are individually selected from H, a C-1 to C-5 alkyl, a halide, a C-1 to C-5 alkyloxy and said oligo flexible tethered groups,
wherein further at least one R₃, R₄, R₅, R₆, and R₇, is selected from said oligo flexible tethered groups, unless the moiety E-A-L in structure (5) contains at least one said oligo flexible tethered group,
L is either a direct valence bond or a linking moiety derived from a 1,1-diarylethene;
A segment is said polar block copolymer segment comprised either alkyl 2-methylenealkanoate derived repeating units, lactone derived repeat units, oxirane derived repeat units, oxetane derived repeating units, or cyclic carbonate derived repeat units;
E is said end groups selected from H, an alkyl, a carbonylalkyl (—C═O-alkyl), a carbonyloxyalkyl (—C═O—O-alkyl), and an alkyl 2-arylacrylate derived end group (—CH₂—CH(Aryl)(C(═O))—O-alkyl) and n4 is the number of repeat units;

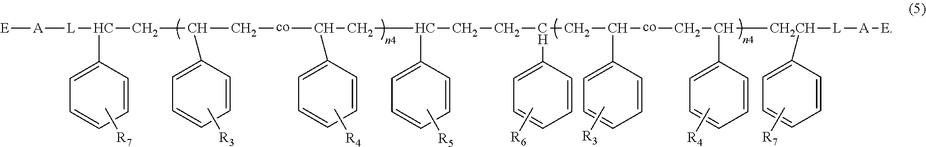

38-44. (canceled)

45. The block copolymer of claim 37, wherein in structure (5) E-A-L has structure (3a), wherein;
* represents the attachment point of the E-A-L moiety to B,
R₁, and R₂, are individually selected from H, a C-1 to C-5 alkyl, a halide, a C-1 to C-5 alkyloxy and said oligo flexible tethered groups,
R₈, and R₉, are individually selected from a C-1 to C-5 alkyl, and said oligo flexible tethered groups,
R₁₀ is H or a C-1 to C-5 alkyl,
R₁₁ is H, C-1 to C-5 alkyl, a halide or a C-1 to C-5 alkyloxy; wherein further at least one R₁, R₂, R₈, and R₉, is selected from said oligo flexible tethered groups, unless said B has at least one said oligo flexible tethered group, and n5 is the number of repeat units;

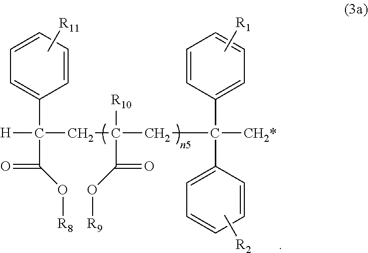

46-58. (canceled)

59. The block copolymer of claim 37, wherein in structure (5) E-A-L has structure (4a), wherein * represents the attachment point of the E-A-L moiety to B,
R₁, and R₂, are individually selected from H, a C-1 to C-5 alkyl, a halide, a C-1 to C-5 alkyloxy and said oligo flexible tethered groups,
R₉ₐ and R_{9b} are individually selected from a C-1 to C-5 alkyl, and said oligo flexible tethered groups,
R₁₀ₐ and R_{10b} are individually selected from H or a C-1 to C-5 alkyl,
R₁₂ is H or a C-1 to C-5 alkyl, wherein further,
at least one R₁, R₂, R₉ₐ and R_{9b} is selected from said oligo flexible tethered groups, unless said B has at least one said oligo flexible tethered group, wherein n6 and n7 are the number of repeat units;

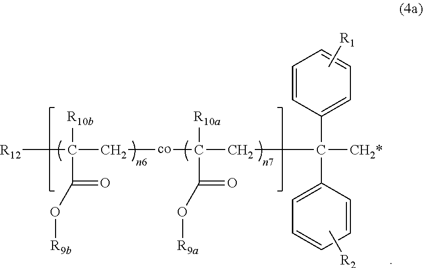

60-73. (canceled)

74. A block copolymer having structure (6), wherein
A₁ is a polar block copolymer segment, which has a T_{g} of about 50° C. to about 100° C., comprised of either alkyl 2-methylenealkanoate derived repeating units, lactone derived repeat units, oxirane derived repeat units, oxetane derived repeating units, or cyclic carbonate derived repeat units;
B₁ is a styrenic block copolymer segment, which has a T_{g} from about 50° C. and to about 100° C.
B₂ is block copolymer segment with a T_{g} ranging from about −5° C. to about −50° C., which comprises repeat units derived from either an olefin selected from the group consisting of an alkene, an alkadiene, and an alkatriene, or a from mixture of at two different olefins selected from this group;
L₁ is either a direct valence bond or a linking moiety derived from a 1,1-diarylethene; wherein
E₁ are end groups selected from H, an alkyl, a carbonylalkyl (—C═O-alkyl), a carbonyloxyalkyl (—C═O—O-alkyl, and an alkyl 2-arylacrylate derived end group (—CH₂—CH(Aryl)(C(═O))—O-alkyl), and further wherein
said block copolymer has a polydispersity ranging from 1 to about 1.09;

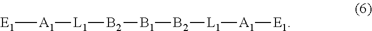

75-77. (canceled)

78. The block copolymer of claim 74, wherein said B₂ is comprised of a mixture of at least two different olefinic repeat units having structures (7a), (7b), (7c), and (7d), derived from an alkadiene; wherein R_{d}, R_{d1}, R_{d2}, R_{d3}, Rₑ, Rₑ₁, Rₑ₂, and Rₑ₃, are individually selected from the group consisting of a H, and a C-1 to C-8 alkyl, and further wherein the total mole % of these olefinic repeat units in said block copolymer ranges from about 3 mole % to about 50 mole %;

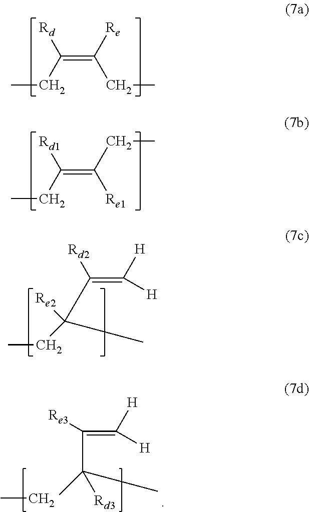

79. The block copolymer of claim 74, wherein R_{d}, R_{d1}, R_{d2}, and R_{d3} are the same and are selected from a H, or a C-1 to C-8 alkyl, and Rₑ, Rₑ₁, Rₑ₂, and Rₑ₃, are and are selected from a H, or a C-1 to C-8 alkyl,

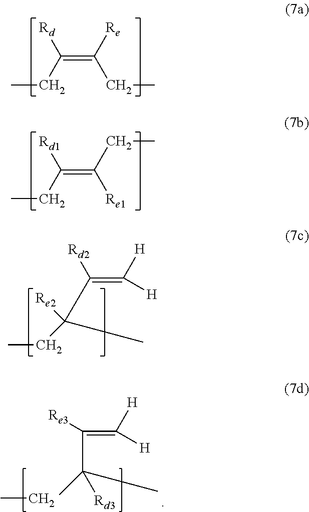

80-92. (canceled)

93. The block copolymer of claim 74, having structure (7) which comprises a central non-polar styrenic block copolymer segment attached at either end to the moiety —B₂-A₁-E₁ wherein R₁ₐ, R₂ₐ, R₃ₐ, R₄ₐ, R₅ₐ, R₆ₐ, and R₇ₐ, are individually selected from H, a C-1 to C-5 alkyl, a halide, a C-1 to C-5 alkyloxy, n8 is the number of repeat units;

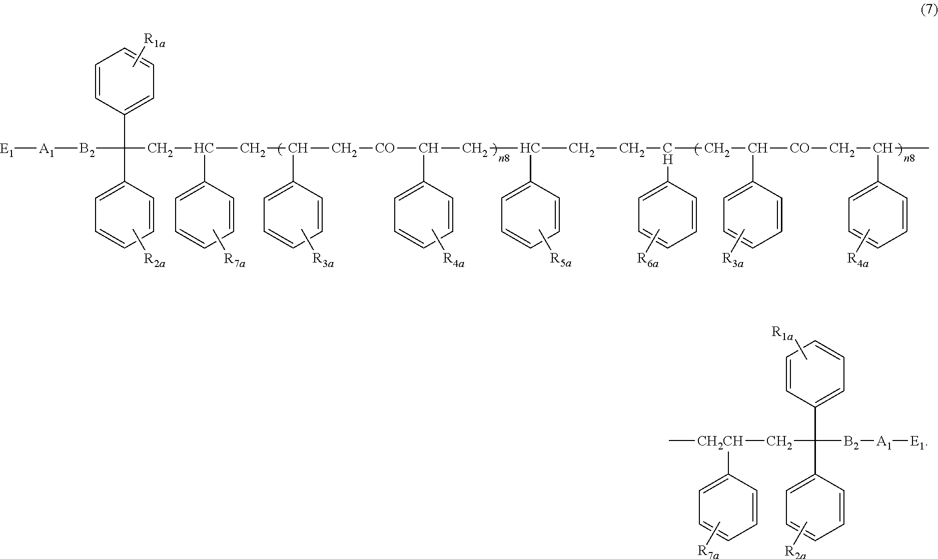

94. (canceled)

95. The block copolymer of claim 93, wherein said B₂ is comprised of a mixture of at least two different olefinic repeat units having structures (7a), (7b), (7c), and (7d); wherein R_{d}, R_{d1}, R_{d2}, R_{d3}, Rₑ, Rₑ₁, Rₑ₂, and Rₑ₃, are individually selected from the group consisting of a H, and a C-1 to C-8 alkyl, and further wherein the total mole % of these olefinic repeat units in said block copolymer ranges from about 3 mole % to about 50 mole %;

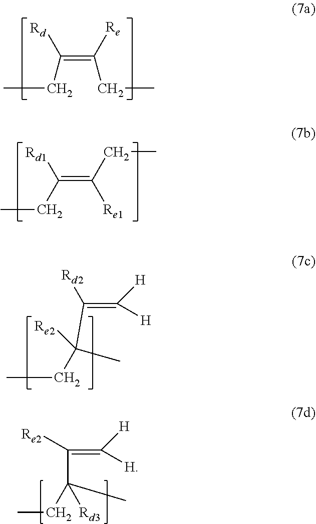

96. The block copolymer of claim 93, wherein R_{d}, R_{d1}, R_{d2}, and R_{d3} are the same and are selected from a H, or a C-1 to C-8 alkyl, and Rₑ, Rₑ₁, Rₑ₂, and Rₑ₃, are and are selected from a H, or a C-1 to C-8 alkyl.

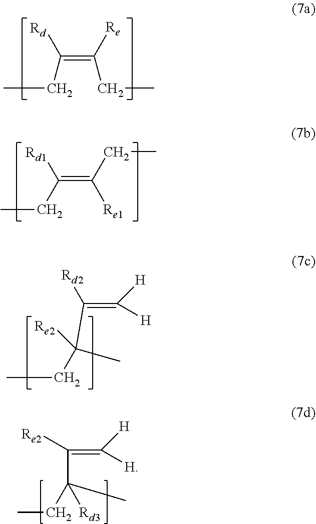

97-101. (canceled)

102. A composition comprising a least one block copolymer of claim 1 and a spin casting solvent.

103. (canceled)

104. (canceled)

105. A method of vertically orienting first and second block copolymer domains over an unpatterned substrate using a layer of a block copolymer having a periodicity of L₀ comprising the steps of:
a) forming a coating layer of a block copolymer from the composition of claim 102 on said unpatterned substrate; and,
b) annealing the layer of the block copolymer to generate a non-zero positive integer number of first and second block copolymer domains, vertically oriented on said unpatterned substrate.

106. A method of vertically orienting first and second block copolymer domains over a first patterned substrate where the height of topography of the pattern on the substrate is at least 0.7 times L₀ and aligning the domains with the pattern, using a coating comprised of a block copolymer having a periodicity of L₀ comprising the steps of:
a1) forming a coating layer of the composition of claim 102 on said first topographical substrate, wherein the thickness of the average thickness of the coating layer of the block copolymer is less than the height of the topography of the first topographical substrate, wherein the block copolymer layer is laterally confined by the topography; and,
b1) annealing the block copolymer layer to generate first and second block copolymer domains, vertically oriented on said first patterned substrate, and confined within the recessed region.

107. A method of vertically orienting, first and second block copolymer domains with a periodicity of L₀ over a second patterned substrate having a topographical pattern with the height of topography larger than 0.7 times L₀ and a pitch P1 where the pitch P1 is a non-zero positive integer multiplied by L₀, and aligning the domains with the pattern comprising the steps of:
a2) forming a coating layer of a block copolymer with the composition of claim 102 on said second patterned substrate, where the thickness of the coating layer of the block copolymer is more than the height of the topography of the second patterned substrate; and,
b2) annealing the block copolymer layer to generate a non-zero positive integer number of first and second block copolymer domains vertically oriented on said second patterned substrate and aligning them to the second patterned substrate where the sum of vertically oriented domains is equal or larger than the pitch P1 the of topographical pattern.

108. A method of vertically orienting first and second block copolymer domains over a substrate having a surface chemical prepattern having a pitch P2, where the pitch P2 is a non-zero positive integer multiplied by L₀ and aligning the domains comprising the steps of:
a) forming a coating layer of a block copolymer with the composition of claim 102 on the substrate having a surface chemical prepattern; and,
b) annealing the block copolymer layer to generate vertically oriented first and second block copolymer domains aligned with the substrate having a surface chemical prepattern having a pitch P2.

109. A composition comprising the block copolymer of claim 73 and a solvent.

110. (canceled)

111. (canceled)

112. A method of vertically orienting first and second block copolymer domains over an unpatterned substrate using a layer of a block copolymer having a periodicity of L₀ comprising the steps of:
a) forming a coating layer of a block copolymer from the composition of claim 109 on said unpatterned substrate; and,
b) annealing the layer of the block copolymer to generate a non-zero positive integer number of first and second block copolymer domains, vertically oriented on said unpatterned substrate.

113. A method of vertically orienting first and second block copolymer domains over a first patterned substrate where the height of topography of the pattern on the substrate is at least 0.7 times L₀ and aligning the domains with the pattern, using a coating comprised of a block copolymer having a periodicity of L₀ comprising the steps of:
a1) forming a coating layer of the composition of claim 109 on said first topographical substrate, wherein the thickness of the average thickness of the coating layer of the block copolymer is less than the height of the topography of the first topographical substrate, wherein the block copolymer layer is laterally confined by the topography; and,
b1) annealing the block copolymer layer to generate first and second block copolymer domains, vertically oriented on said first patterned substrate, and confined within the recessed region.

114. A method of vertically orienting, first and second block copolymer domains with a periodicity of L₀ over a second patterned substrate having a topographical pattern with the height of topography larger than 0.7 times L₀ and a pitch P1 where the pitch P1 is a non-zero positive integer multiplied by L₀, and aligning the domains with the pattern comprising the steps of:
a2) forming a coating layer of a block copolymer with the composition of claim 109 on said second patterned substrate, where the thickness of the coating layer of the block copolymer is more than the height of the topography of the second patterned substrate; and,
b2) annealing the block copolymer layer to generate a non-zero positive integer number of first and second block copolymer domains vertically oriented on said second patterned substrate and aligning them to the second patterned substrate where the sum of vertically oriented domains is equal or larger than the pitch P1 the of topographical pattern.

115. A method of vertically orienting first and second block copolymer domains over a substrate having a surface chemical prepattern having a pitch P2, where the pitch P2 is a non-zero positive integer multiplied by L₀ and aligning the domains comprising the steps of:
a) forming a coating layer of a block copolymer with the composition of claims 109 to 111 on the substrate having a surface chemical prepattern; and,
b) annealing the block copolymer layer to generate vertically oriented first and second block copolymer domains aligned with the substrate having a surface chemical prepattern having a pitch P2.

116. A compound of structure (C1), wherein R_{1b}, R_{1c}, R_{2b} and R_{2c} are individually selected from H, a halide, a C-1 to C-4 alkyl, a C-1 to C-4 alkyloxy and an oligo flexible tethered groups, wherein at least one of R_{1b}, R_{2b}, R_{1c} and R_{2c} is an oligo flexible tethered group and R_{3b}, R_{3c}, R_{4b}, R_{4c}, R_{5b} and R_{5c} are individually selected from H, a halide, a C-1 to C-4 alkyl, and a C-1 to C-4 alkyloxy; wherein said oligo flexible tethered group is an oligo ether tethered group or an oligo dialkyl siloxane tethered group.

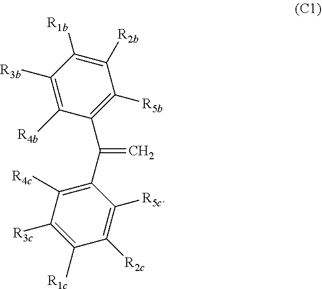

117-125. (canceled)

126. The compound of claim 116, wherein said flexible oligo flexible tethered group is an oligo ether tethered group.

127. The compound of claim 116, wherein said flexible oligo flexible tethered groups is an oligo dialkyl siloxane tethered group.

128. The compound of claim 116, which has structure (C1-A), wherein a is 7 to 19;

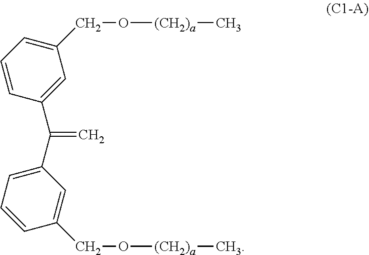

129. The compound of claim 116, which has structure (C1-B), wherein a is 7 to 19;

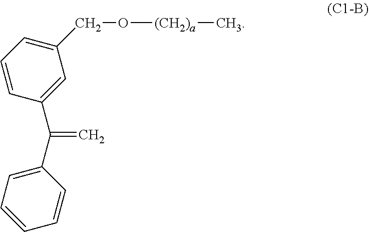

130. (canceled)

131. The compound of claim 116, which has structure (C1-D), wherein a is 7 to 19;

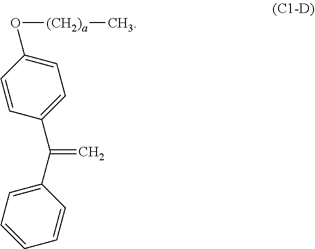

132. The compound of claim 116, which has structure (C1-E), wherein e2 is 2 to 8, and e3 is 1 to 8.

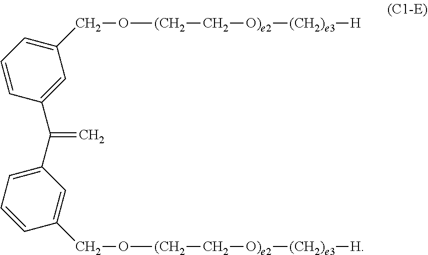

133. The compound of claim 116, which has structure (C1-F), wherein e2 is 2 to 8 and e3 is 1 to 8;

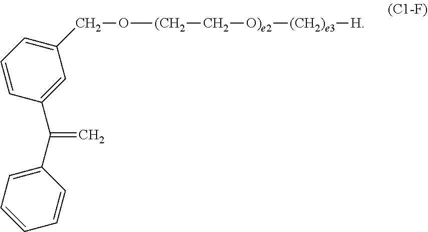

134. The compound of claim 116, which has structure (C1-G), wherein e2 is 2 to 8, and e3 is 1 to 8.

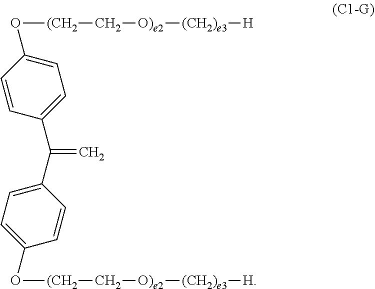

135. The compound of claim 116, which, has structure (C1-H), wherein e2 is 2 to 8, and e3 is 1 to 8

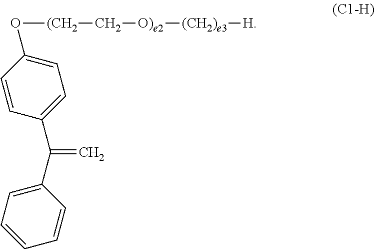

136. The compound of claim 116, which has structure (C1-I), wherein s is 6 to 18, and the alkyl moiety is a C-1 to C-8 alkyl;

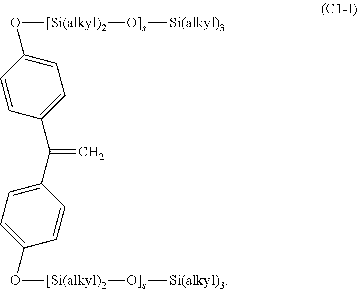

137. The compound of claim 116 which, has structure (C1-J), wherein s is 6 to 18, and the alkyl moiety is a C-1 to C-8 alkyl;

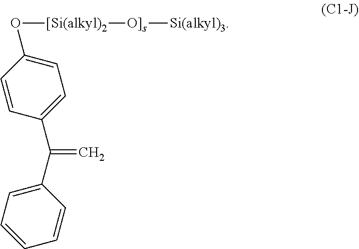

138. The compound of claim 116, which has structure (C1-K), wherein s is 6 to 18, and the alkyl moiety is a C-1 to C-8 alkyl;

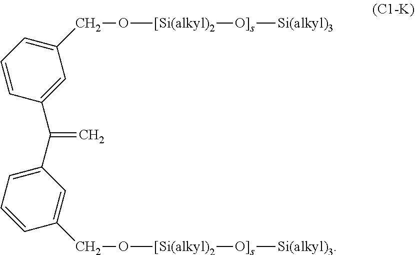

139. The compound of claim 116 which has structure (C1-L), wherein s is 6 to 18, and the alkyl moiety is a C-1 to C-8 alkyl;

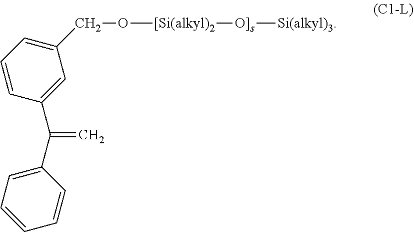

140. (canceled)
